(19) United States
(12) Patent Application Publication
(10) Pub. No.: US 2026/0016727 A1
(43) Pub. Date: Jan. 15, 2026

(54) DISPLAY PANEL AND DISPLAY DEVICE

(71) Applicants: Hefei Xinsheng Optoelectronics Technology Co., Ltd., Hefei, Anhui (CN); BOE Technology Group Co., Ltd., Beijing (CN)

(72) Inventors: Ran ZHANG, Beijing (CN); Xiaofang GU, Beijing (CN); Xiaoye MA, Beijing (CN); Yanchun LU, Beijing (CN); Yongcan WANG, Beijing (CN); Quan GAN, Beijing (CN)

(73) Assignees: Hefei Xinsheng Optoelectronics Technology Co., Ltd., Hefei, Anhui (CN); BOE Technology Group Co., Ltd., Beijing (CN)

(21) Appl. No.: 18/993,579

(22) PCT Filed: Apr. 18, 2024
(86) PCT No.: PCT/CN2024/088481

§ 371 Date: Jan. 13, 2025

(30) Foreign Application Priority Data
May 24, 2023 (CN) 202310596135.8

(51) Int. Cl. G02F 1/1368; G02F 1/1343; G02F 1/1362; H10D 86/40

(52) U.S. Cl. CPC G02F 1/1368; G02F 1/134309; G02F 1/136209; G02F 1/136286; H10D 86/441

(57) ABSTRACT

Provided is display panel. The display panel includes: a base substrate; multiple first signal traces, multiple second signal traces, multiple pixel circuits arranged in an array, multiple pixel electrodes corresponding to the plurality of pixel circuits, a common electrode provided with multiple first openings corresponding to the plurality of pixel circuits, and a black matrix layer, wherein an orthographic projection of each first opening on the base substrate covers orthographic projections of the first connection position, the second connection position, and the third connection position of the pixel circuit corresponding to the first opening on the base substrate, and an orthographic projection of the black matrix layer on the base substrate covers orthographic projections of the first openings on the base substrate.

This application claims priority to Chinese Patent Application No. 202310596135.8, filed on May 24, 2023 and entitled “DISPLAY PANEL AND DISPLAY DEVICE”, the contents of which are incorporated herein by reference in its entirety.

### TECHNICAL FIELD

The present disclosure relates to the field of display technologies, in particular to a display panel and a display device.

### BACKGROUND

Liquid crystal display (LCD) panels are widely used in large-size display devices due to their low power consumption.

### SUMMARY

The present disclosure provides a display panel and a display device. The technical solutions are as follows.

On one aspect, a display panel is provided, the display panel includes:
base substrate;
multiple first signal traces disposed on the base substrate, wherein the first signal traces are arranged along a first direction and extend along a second direction, the second direction intersecting with the first direction;
multiple second signal traces disposed on the base substrate, wherein the second signal traces are arranged along the second direction and extend along the first direction;
multiple pixel circuits arranged in an array, wherein each of the pixel circuits is connected to one of the first signal traces by a first connection position and is connected to one of the second signal traces by a second connection position;
multiple pixel electrodes corresponding to the multiple pixel circuits, wherein each of the pixel electrodes is connected to a pixel circuit corresponding to the pixel electrode by a third connection position, and the pixel circuit transmits, under the control of the first signal trace, a driving signal from the second signal trace to the pixel electrode;
a common electrode provided with multiple first openings corresponding to the multiple pixel circuits, wherein an orthographic projection of each first opening on the base substrate covers orthographic projections on the base substrate of the first connection position, the second connection position, and the third connection position of the pixel circuits corresponding to the first opening; and
a black matrix layer, wherein an orthographic projection of the black matrix layer on the base substrate covers orthographic projections of the first openings on the base substrate.

In some embodiments, the common electrode is further provided with multiple second openings, orthographic projections of the second openings on the base substrate fall within the orthographic projection of the black matrix layer on the base substrate;
for each of the second openings, an orthographic projection of the second opening on the base substrate covers a part of an orthographic projection of one of the second signal traces on the base substrate, the second opening is disposed between two adjacent first openings in the first direction and there are gaps between the second opening and the adjacent first openings in the first direction.

In some embodiments, the first opening includes a first region and a second region in communication with the first region; and
an orthographic projection of the first region on the base substrate partially overlaps a projection overlapping region of the first signal trace and the second signal trace, an orthographic projection of the second region on the base substrate at least covers the orthographic projection of the third connection position on the base substrate;
wherein a length of the second region in the first direction is different from a length of the first region in the first direction.

In some embodiments, the display panel further includes multiple third signal traces arranged along the first direction and extending along the second direction;
wherein each of the third signal traces is connected to the common electrode.

In some embodiments, the display panel includes a gate layer, a first insulating layer, an active layer, a source-drain layer, a second insulating layer, a common electrode layer, a third insulating layer, and a pixel electrode layer that are stacked sequentially along a direction away from the base substrate;
wherein the gate layer includes the multiple first signal traces and the multiple third signal traces, the active layer includes multiple active patterns, and the source-drain electrode layer includes the multiple second signal traces arranged along the second direction with gaps, a first connection portion, and a second connection portion, the common electrode layer includes the common electrode, and the pixel electrode layer includes the multiple pixel electrodes and a third connection portion; and
a target portion of the second signal trace is connected to the active pattern, one end of the first connection portion is connected to the active pattern, another end of the first connection portion is connected to the pixel electrode, the second connection portion is connected to the common electrodes via the third connection portion, and the second connection portion is connected to the third signal trace.

In some embodiments, an orthographic projection of the third connection portion on the base substrate includes a first projection region and a second projection region;
the first projection region overlaps the orthographic projection of the first opening on the base substrate, and the second projection region overlaps an orthographic projection of the common electrode on the base substrate; and
a part of the third connection portion corresponding to the first projection region is connected to the second connection portion, and a part of the third connection portion corresponding to the second projection region is connected to the common electrode.

In some embodiments, the orthographic projection of the first opening on the base substrate covers a target overlapping region;
wherein the target overlapping region is an overlapping region of an orthographic projection of the third signal trace on the base substrate and an orthographic projection of the second signal trace on the base substrate.

In some embodiments, the display panel further includes multiple fourth signal traces arranged along the second direction and extending along the first direction, wherein each of the fourth signal traces is connected to the common electrode;
the common electrode is further provided with multiple third openings; for each of the third openings, an orthographic projection of the third opening partially overlaps an orthographic projection of one of the fourth signal traces on the base substrate, and the third opening is disposed between two adjacent first openings in the first direction and there are gaps between the second opening and the adjacent first openings in the first direction.

In some embodiments, the orthographic projection of the first opening on the base substrate partially overlaps an orthographic projection of the first signal trace on the base substrate; and
the orthographic projection of the third opening on the base substrate falls outside the orthographic projection of the black matrix layer on the base substrate.

In some embodiments, the display panel further includes a gate layer, a first insulating layer, an active layer, a source-drain layer, a second insulating layer, a common electrode layer, a third insulating layer, and a pixel electrode layer that are stacked sequentially along a direction away from the base substrate;
wherein the gate layer includes the multiple first signal traces, the active layer includes multiple active patterns, the source-drain layer includes the multiple second signal traces, the multiple fourth signal traces, and a first connection portion, the common electrode layer includes the common electrode, and the pixel electrode layer includes the multiple pixel electrodes;
a target portion of the second signal trace is connected to the active pattern, one end of the first connection portion is connected to the active pattern, and another end of the first connection portion is connected to the pixel electrode.

In some embodiments, the pixel circuit includes a switching transistor, and the switching transistor includes a gate, a source, and a drain;
wherein the first signal trace includes a signal trace body and a signal trace pattern that are in a one-piece structure, the signal trace pattern serving as the gate of the switching transistor;
an orthographic projection of the active pattern on the base substrate includes a source region, a drain region and a channel region between the source region and the drain region, a part of the first connection portion that overlaps and is connected to the drain region serves as the drain of the switching transistor, the target portion of the second signal traces serves as the source of the switching transistor, and the channel region is an area where the signal trace pattern overlaps the active pattern and does not overlap either the first connection portion or the second signal trace.

In some embodiments, an orthographic projection of the source region on the base substrate is located within an orthographic projection of the signal trace pattern on the base substrate;
an orthographic projection of the drain region on the base substrate includes a third projection region located within the orthographic projection of the signal trace pattern on the base substrate, and a fourth projection region located outside the orthographic projection of the signal trace pattern on the base substrate.

In some embodiments, the active pattern has a first active boundary and a second active boundary that extend along the first direction and are opposed to each other, the first active boundary being a boundary, distal to the source region, of the drain region, and the second active boundary being a boundary, distal to the drain region, of the source region;
the signal trace pattern has a first pattern boundary extending along the first direction, and the first connection portion has a connection portion boundary extending along the first direction; and
an orthographic projection of the first pattern boundary on the base substrate is located between an orthographic projection of the first active boundary on the base substrate and an orthographic projection of the connection portion boundary on the base substrate;
wherein a distance between the first pattern boundary and the connection portion boundary in the second direction is less than 3 micrometers.

In some embodiments, the signal trace pattern has a second pattern boundary extending along the second direction and distal to a side of the signal trace body; the active pattern has a third active boundary and a fourth active boundary that extend along the second direction and are opposed to each other, the third active boundary being closer to the second pattern boundary relative to the fourth active boundary being;
wherein a distance between the second pattern boundary and the third active boundary in the first direction is less than or equal to 3 micrometers.

In some embodiments, an overlapping region between the orthographic projection of the second signal trace on the base substrate and the orthographic projection of the signal trace pattern on the base substrate includes a first overlapping region and a second overlapping region;
wherein a length of the first overlapping region in the first direction is less than or equal to the distance between the second patterned boundary and the third active boundary in the first direction, and a length of the second overlapping region in the first direction is a distance between the third active boundary and the fourth active boundary in the first direction.

In some embodiments, the second signal trace has a first trace boundary and a second trace boundary extending along the first direction, at least a part of an orthographic projection of the first trace boundary on the base substrate and at least a part of an orthographic projection of the second trace boundary on the base substrate are both located within the orthographic projection of the signal trace pattern on the base substrate;
wherein a distance between the first trace boundary and the second trace boundary in the second direction is less than or equal to 3 micrometers.

In some embodiments, the display panel further includes an array substrate and a color filter substrate that are oppositely arranged to form a cell, and a liquid crystal layer disposed between the array substrate and the color filter substrate;
wherein the array substrate includes the multiple first signal traces, the multiple second signal traces, the multiple pixel circuits, the multiple pixel electrodes, and the common electrode; and the color filter substrate includes the black matrix layer.

On a second aspect, a display device is provided. The display device includes a power assembly and a display panel as defined in any one of the above embodiments;
wherein the power assembly is configured to supply power to the display panel.

### BRIEF DESCRIPTION OF THE DRAWINGS

To describe the technical solutions in the embodiments of the present disclosure more clearly, the following briefly introduces the accompanying drawings required for describing the embodiments. Apparently, the accompanying drawings in the following description illustrate merely some embodiments of the present disclosure, and a person of ordinary skill in the art may still derive other drawings from these accompanying drawings without creative efforts.

FIG. 1 is a schematic partial diagram of a display panel according to some embodiments of the present disclosure;

FIG. 2 is a schematic partial diagram of another display panel according to some embodiments of the present disclosure;

FIG. 3 is a schematic diagram of a common electrode in the display panel shown in FIG. 1;

FIG. 4 is a schematic diagram of a common electrode in the display panel shown in FIG. 2;

FIG. 5 is a schematic partial diagram of a display panel according to some embodiments of the present disclosure;

FIG. 6 is a schematic diagram of a common electrode in the display panel shown in FIG. 5;

FIG. 7 is a top view of a base substrate according to some embodiments of the present disclosure;

FIG. 8 is a schematic diagram of a connection relationship of a pixel circuit according to some embodiments of the present disclosure;

FIG. 9 is a partial cross-sectional view of a display panel according to some embodiments of the present disclosure;

FIG. 10 is a partial top view of a gate layer according to some embodiments of the present disclosure;

FIG. 11 is a partial top view of a first insulating layer according to some embodiments of the present disclosure;

FIG. 12 is a partial top view of an active layer according to some embodiments of the present disclosure;

FIG. 13 is a schematic partial diagram of a lamination of a gate layer, a first insulating layer, and an active layer according to some embodiments of the present disclosure;

FIG. 14 is a partial top view of a source-drain layer according to some embodiments of the present disclosure;

FIG. 15 is a schematic partial diagram of a lamination of a gate layer, a first insulating layer, an active layer, and a source-drain layer according to some embodiments of the present disclosure;

FIG. 16 is a schematic diagram of a planarization layer according to some embodiments of the present disclosure;

FIG. 17 is a schematic partial diagram of a lamination of a gate layer, a first insulating layer, an active layer, a source-drain layer, and a planarization layer according to some embodiments of the present disclosure;

FIG. 18 is a sectional view in a direction A-A in FIG. 17;

FIG. 19 is a schematic partial diagram of a lamination of a gate layer, a first insulating layer, an active layer, a source-drain layer, a planarization layer, and a common electrode layer according to some embodiments of the present disclosure;

FIG. 20 is a sectional view in a direction B-B in FIG. 19;

FIG. 21 is a partial top view of a third insulating layer according to some embodiments of the present disclosure;

FIG. 22 is a schematic partial diagram of a lamination of a gate layer, a first insulating layer, an active layer, a source-drain layer, a planarization layer, a common electrode layer, and a third insulating layer according to some embodiments of the present disclosure;

FIG. 23 is a sectional view in a direction C-C in FIG. 19;

FIG. 24 is a partial top view of a pixel electrode layer according to some embodiments of the present disclosure;

FIG. 25 is a schematic partial diagram of a lamination of a gate layer, a first insulating layer, an active layer, a source-drain layer, a planarization layer, a common electrode layer, a third insulating layer, and a pixel electrode layer according to some embodiments of the present disclosure;

FIG. 26 is a sectional view in a direction D-D in FIG. 25;

FIG. 27 is a schematic diagram of a black matrix layer in the display panel shown in FIG. 1;

FIG. 28 is a schematic partial diagram of a lamination of a gate layer, a first insulating layer, an active layer, a source-drain layer, a planarization layer, and a common electrode layer according to some embodiments of the present disclosure;

FIG. 29 is a schematic partial diagram of a lamination of a gate layer, a first insulating layer, an active layer, a source-drain layer, a planarization layer, a common electrode layer, and a third insulating layer according to some embodiments of the present disclosure;

FIG. 30 is a schematic partial diagram of a lamination of a gate layer, a first insulating layer, an active layer, a source-drain layer, a planarization layer, a common electrode layer, a third insulating layer, and a pixel electrode layer according to some embodiments of the present disclosure;

FIG. 31 is a partial top view of a gate layer according to some embodiments of the present disclosure;

FIG. 32 is a partial top view of an active layer according to some embodiments of the present disclosure;

FIG. 33 is a schematic partial diagram of a lamination of a gate layer, a first insulating layer, and an active layer according to some embodiments of the present disclosure;

FIG. 34 is a partial top view of a source-drain layer according to some embodiments of the present disclosure;

FIG. 35 is a schematic partial diagram of a lamination of a gate layer, a first insulating layer, an active layer, and a source-drain layer according to some embodiments of the present disclosure;

FIG. 36 is a partial top view of another planarization layer according to some embodiments of the present disclosure;

FIG. 37 is a schematic partial diagram of a lamination of a gate layer, a first insulating layer, an active layer, a source-drain layer, and a planarization layer according to some embodiments of the present disclosure;

FIG. 38 is a schematic partial diagram of a lamination of a gate layer, a first insulating layer, an active layer, a source-drain layer, a planarization layer, and a common electrode layer according to some embodiments of the present disclosure;

FIG. 39 is a partial top view of a third insulating layer according to some embodiments of the present disclosure;

FIG. 40 is a schematic partial diagram of a lamination of a gate layer, a first insulating layer, an active layer, a source-drain layer, a planarization layer, a common electrode layer, and a third insulating layer according to some embodiments of the present disclosure;

FIG. 41 is a partial top view of a pixel electrode layer according to some embodiments of the present disclosure;

FIG. 42 is a schematic partial diagram of a lamination of a gate layer, a first insulating layer, an active layer, a source-drain layer, a second insulating layer, a common electrode layer, a third insulating layer, and a pixel electrode layer according to some embodiments of the present disclosure;

FIG. 43 is a schematic diagram of a black matrix layer in the display panel shown in FIG. 5;

FIG. 44 is a schematic partial diagram of a gate layer, an active layer, and a source-drain layer according to some embodiments of the present disclosure;

FIG. 45 is a schematic partial diagram of a gate layer, an active layer, and a source-drain layer according to some embodiments of the present disclosure;

FIG. 46 is a schematic diagram of a light leakage simulation according to some embodiments of the present disclosure;

FIG. 47 is a schematic partial diagram of a gate layer, an active layer, and a source-drain layer in the related art;

FIG. 48 is a partially enlarged schematic view of the display panel shown in FIG. 1;

FIG. 49 is a partially enlarged schematic view of the display panel shown in FIG. 5; and

FIG. 50 is a schematic structural diagram of a display device according to some embodiments of the present disclosure.

### DETAILED DESCRIPTION

To make the objective, technical solutions, and advantages of the present disclosure clearer, embodiments of the present disclosure will be further described in detail with reference to the accompanying drawings.

In the related art, the LCD panel includes a base substrate, a common electrode, a pixel electrode, and a liquid crystal layer that are disposed on the base substrate. And, the LCD panel further includes a common electrode driving circuit disposed in a peripheral region of the base substrate, and a pixel electrode driving circuit disposed in a display region of the base substrate. Wherein, the common electrode driving circuit is connected to the common electrode and is used to provide the common electrode driving signal for the common electrode, and the pixel electrode driving circuit is connected to the pixel electrode and is used to provide the pixel electrode driving signal for the pixel electrode. And, the common electrode driving signal and the pixel electrode driving signal jointly drive the liquid crystal molecules in the liquid crystal layer to deflect, thereby realizing light transmission of the LCD panel.

However, the coupling capacitance in the LCD panel is relatively large, which leads to higher power consumption of the LCD panel, and the LCD panel is prone to heating, thereby adversely affecting the yield of the LCD panel.

LCD panels have been widely used in the field of display. With the intensification of competition in the panel industry, the quality requirements for a-Si products and oxide products are getting closer to those for low-temperature poly-silicon (LTPS) products. Among them, a-Si products refer to non-crystalline silicon thin-film transistors in the display panel, oxide products refer to oxide thin-film transistors in the display panel, and LTPS products refer to LTPS thin-film transistors in the display panel.

LTPS is a low-temperature poly-silicon with ultra-high mobility and charging rate. Therefore, under the identical resolution and refresh rate, LTPS can achieve the target charging rate with a thin-film transistor of a smaller channel, which results in a lower voltage drop (loading) and power consumption for LTPS, much less than oxide products. With the gradual increase in the application of Oxide products, Oxide LCD products are now required to have a refresh frequency of 600 Hz (hertz). Due to the increase in the refresh frequency, the charge/discharge times of the driving circuits also increase proportionally, which leads to a significant increase in the power consumption of the product and highlights the heating of the drive circuit.

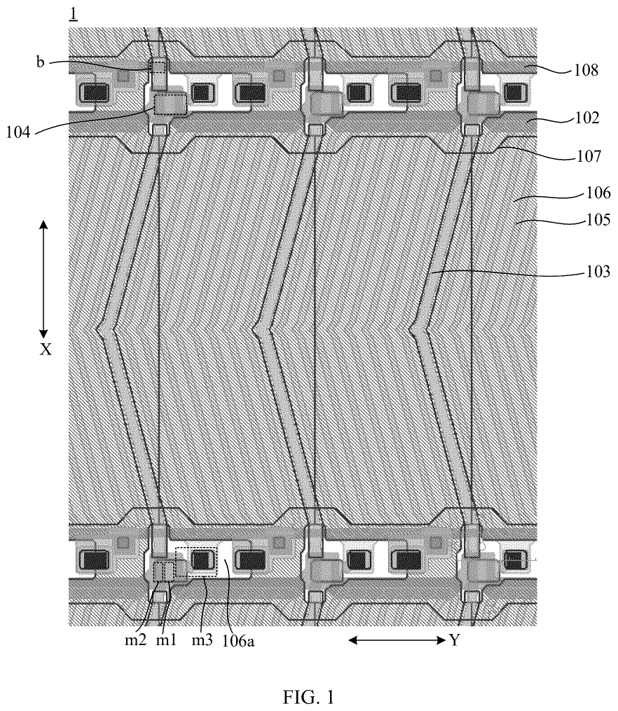

FIG. 1 is a schematic partial diagram of a display panel according to some embodiments of the present disclosure. Referring to FIG. 1, the display panel 1 includes: a base substrate 101, multiple first signal traces 102, multiple second signal traces 103, multiple pixel circuits 104, multiple pixel electrodes 105, a common electrode 106, and a black matrix (BM) layer 107.

The multiple first signal traces 102 are disposed on the base substrate 101. The multiple first signal traces 102 are arranged along the first direction X and extend along the second direction Y. The multiple second signal traces 103 are disposed on the base substrate 101, and the multiple second signal traces 103 are arranged along the second direction Y and extend along the first direction X. The second direction Y intersects with the first direction X. The multiple first signal traces 102 extending along the second direction Y means that the multiple first signal traces 102 are generally oriented in the second direction Y, and the multiple second signal traces 103 extending along the first direction X means that the multiple second signal traces 103 are generally oriented in the first direction X. The first direction X may be a column direction of pixels in the display panel 1, and the second direction Y may be a row direction of pixels in the display panel 1.

The multiple pixel circuits 104 are arranged in an array, and each pixel circuit 104 is connected to a first signal trace 102 via a first connection position m1, and each pixel circuit 104 is connected to a second signal trace 103 via a second connection position m2. The multiple pixel electrodes 105 correspond to the multiple pixel circuits 104 one to one, and each pixel electrode 105 is connected to a pixel circuit 104 corresponding to the pixel electrode 105 via a third connection position m3. That is, each pixel circuit 104 is connected to one first signal trace 102, one second signal trace 103, and one pixel electrode 105 corresponding to the pixel circuit 104.

Each first signal trace 102 is configured to control the state of the pixel circuit 104 connected thereto. In the case that the first signal trace 102 controls the pixel circuit 104 connected thereto to be in the on-state, the pixel circuit 104 receives and transmits the driving signal from the second signal trace 103 to the corresponding pixel electrode 105. That is, each pixel circuit 104 transmits the driving signal from the second signal trace 103 to the corresponding pixel electrode 105 under the control of the first signal trace 102.

Referring to FIG. 1, the common electrode 106 is provided with multiple first openings 106a corresponding to the multiple pixel circuits 104. An orthographic projection of each first opening 106a on the base substrate 101 overlaps the orthographic projections on the base substrate 101 of the first connection position m1, the second connection position m2, and the third connection position m3 of the pixel circuit 104 corresponding to the first opening 106a. That is, the orthographic projection of the common electrode 106 on the base substrate 101 does not overlap the orthographic projection of the connection positions on the base substrate 101.

Typically, the first signal trace 102, the second signal trace 103, and the pixel electrode 105 are all disposed on different layers from the pixel circuit 104. Thus, connection positions between the pixel circuit 104 and the first signal trace 102, the second signal trace 103, or the pixel electrode 105 include at least two conductive film layers. That is, the coupling capacitance is larger at each connection position relative to other positions. By making the orthographic projection of the first opening 106a in the common electrode 106 on the base substrate 101 cover the orthographic projection of the connection positions on the base substrate 101, the coupling capacitance between the common electrode 106 and the conductive film layer at each connection position is avoided, thereby avoiding an abnormal increase of the coupling capacitance at the connection positions. In this way, the display panel 1 is prevented from heating, which ensures the yield of the display panel 1.

In the related art, uncontrollable electric fields may be generated between the signal traces and the pixel electrodes. The common electrode, disposed between the signal traces and the pixel electrodes, can shield the uncontrollable electric fields, thereby preventing light leakage in the display panel.

In the embodiments of the present disclosure, the first opening 106a of the common electrode 106 is a hollow area without the common electrode material, and thus cannot serve to shield the electric field. However, the orthographic projection of the black matrix layer 107 on the base substrate 101 covers the orthographic projection of the first opening 106a on the base substrate 101. Therefore, the light from the first opening 106a is covered by the black matrix layer 107, which avoids the light leakage at the first opening 106a in the display panel 1, thereby ensuring the display effect of the display panel 1.

In summary, according to the display panel provided by the embodiments of the present disclosure, the pixel circuit is connected to the first signal trace via the first connection position, is connected to the second signal trace via the second connection position, is connected to the pixel electrode via the third connection position. Moreover, the orthographic projection of the first opening of the common electrode on the base substrate covers the orthographic projections of the connection positions on the base substrate, such that the coupling capacitance between the common electrode and the conductive film layer at the connection positions is avoided, thereby avoiding the abnormal increase of the coupling capacitance at the connection positions. In this way, the display panel is prevented from heating, which ensures the yield of the display panel.

In some embodiments of the present disclosure, the display panel 1 includes an array substrate and a color filter substrate that are oppositely arranged to form a cell, and a liquid crystal layer disposed between the array substrate and the color filter substrate. The array substrate includes multiple first signal traces 101, multiple second signal traces 102, multiple pixel circuits 104, multiple pixel electrodes 105, and a common electrode 106. The color filter substrate includes a black matrix layer 107.

That is, the multiple first signal traces 101, the multiple second signal traces 102, the multiple pixel circuits 104, the multiple pixel electrodes 105, and the common electrode 106 may be integrated into the array substrate. The black matrix layer 107 is integrated into the color filter substrate.

In some embodiments, the base substrate 101 in the display panel 1 is a substrate for setting up the various structures in the array substrate, and the black matrix layer 107 is integrated into the color filter substrate. In this way, reference 107 shown in FIG. 1 may be used to represent a pattern of the orthographic projection of the black matrix layer 107 on the base substrate 101.

In some embodiments, the pixel electrode 105 and the common electrode 106 are made of a transparent material, such as indium tin oxide (ITO). The first signal trace 102 is a gate signal line for providing a gate signal to the pixel circuit 104. The second signal trace 103 is a data driving signal line for providing a data drive signal to the pixel circuit 104.

In some embodiments of the present disclosure, an area where multiple pixel electrodes 105 are designed in the display panel 1 may be multiple light-transmitting regions of the display panel 1. To avoid mutual interference of light transmitted through multiple light-transmitting regions in the display panel 1, the black matrix layer 107 may generally be disposed between adjacent light-transmitting regions. Therein, adjacent light-transmitting regions in the multiple light-transmitting regions arrayed along the first direction X are demarcated by multiple first signal traces 102, and adjacent light-transmitting regions in the multiple light-transmitting regions arrayed along the second direction Y are demarcated by multiple second signal traces 103. In this way, the orthographic projection of the black matrix layer 107 on the base substrate 101 covers the orthographic projection of the first signal trace 102 on the base substrate 101 and covers the orthographic projection of the second signal trace 103 on the base substrate 101.

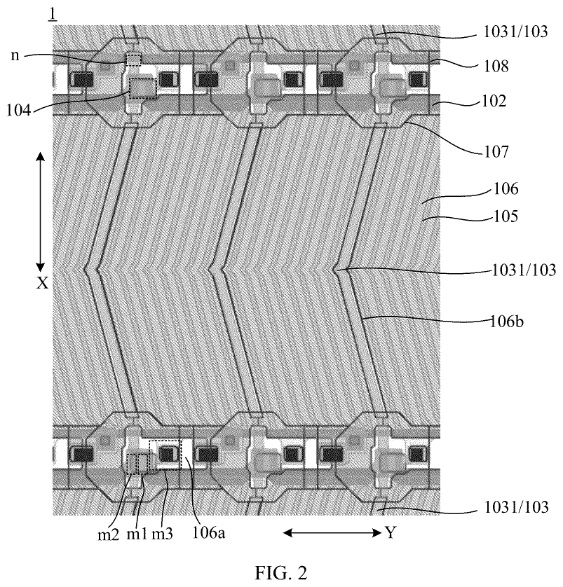

FIG. 2 is a schematic partial diagram of another display panel according to some embodiments of the present disclosure. Referring to FIG. 2, the common electrode 106 also has multiple second openings 106b. An orthographic projection of each second opening 106b on the base substrate 101 covers the orthographic projection of the second signal trace 103 on the base substrate 101.

In some embodiments, each second signal trace 103 extending along the first direction X is divided into multiple first signal line segments 1031 by multiple first signal traces 102 extending along the first direction X. The orthographic projection of each second opening 106b on the base substrate 101 covers the orthographic projection of one first signal line segment 1031 on the base substrate 101. That is, the common electrode 106 is provided with multiple second openings 106b corresponding to each second signal trace 103, the multiple second openings 106b are arranged along an extension direction X of the second signal trace 103 with gaps between adjacent second openings 106b.

Since the orthographic projection of the common electrode 106 on the base substrate 101 does not overlap the orthographic projection of the respective first signal line segment 1031 of the second signal trace 103 on the base substrate 101, the projection overlapping region of the common electrode 106 and the second signal trace 103 is reduced. Further, the coupling capacitance between the common electrode 106 and the second signal trace 103 is reduced, thereby reducing the coupling capacitance of the display panel 1 as a whole, further avoiding the overheating of the display panel 1, and ensuring the yield of the display panel 1.

Moreover, since the orthographic projection of the second opening 106b on the base substrate 101 is located within the orthographic projection of the black matrix layer 107 on the base substrate 101, the light transmitted through the second opening 106b is covered by the black matrix layer 107, avoiding the light leakage from the second opening 106b in the display panel 1, and ensuring the display effect of the display panel 1.

Typically, the first connection position m1, the second connection position m2, and the third connection position m3 are located substantially in the projection overlapping region of the first signal trace 102 and the second signal trace 103, and therefore with reference to FIGS. 1 and 2, the multiple first openings 106a of the common electrode 106 are arranged in the projection overlapping region of the first signal trace 102 and the second signal trace 103.

Referring to FIG. 2, in the case that the common electrode 106 is provided with the multiple second openings 106b, each of the second openings 106b may be disposed between two first openings 106a adjacent in the first direction X, and there is a gap between the second opening 106b and the adjacent first openings 106a in the first direction X. That is, a row of first openings 106a and a row of second openings 106b are staggered in the first direction X and have gaps between each other. This not only reduces the coupling capacitance, but also ensures that the common electrode 106 is in a connected state at the gaps between the first opening 106a and the second opening 106b, which facilitates signal conduction of the common electrode 106 as a whole.

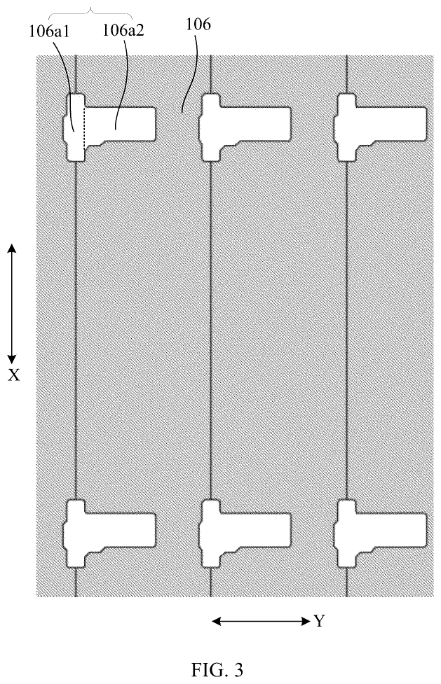

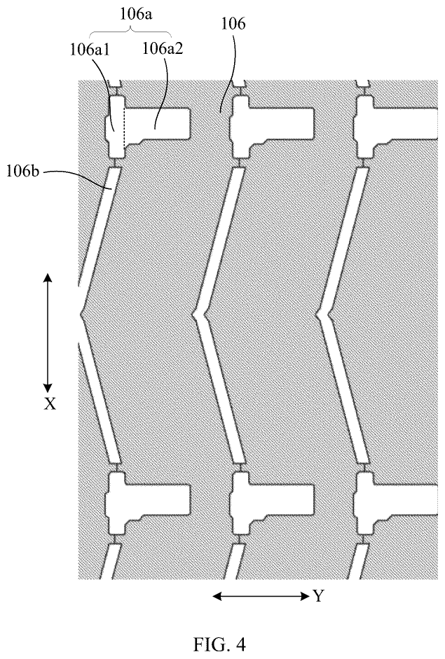

Referring to FIGS. 3 and 4, the first opening 106a includes a first region 106a1 and a second region 106a2 in communication with the first region 106a1. An orthographic projection of the first region 106a1 on the base substrate 101 overlaps the projection overlapping region of the first signal trace 102 and the second signal trace 103. In this way, the coupling capacitance is avoided between the part of the common electrode 106 corresponding to the first region 106a1 and the first signal trace 102 or the second signal trace 103. An orthographic projection of the second region 106a2 on the base substrate 101 at least covers the orthographic projection of the third connection position m3 on the base substrate 101. In this way, the coupling capacitance is avoided between the common electrode 106 and the conductive film layer corresponding to the third connection position m3 by making the second region 106a2 cover the third connection position m3.

In some embodiments, referring to FIGS. 1 to 4, the second regions 106a2 are disposed between multiple light-transmitting regions arranged along the first direction X, and the second regions 106a2 in communication with the first regions 106a1 are arranged along the second direction Y. In combination with FIGS. 2 and 4, the first opening 106a and the second opening 106b of the common electrode 106 for covering the same second signal trace 103 are arranged along the first direction X.

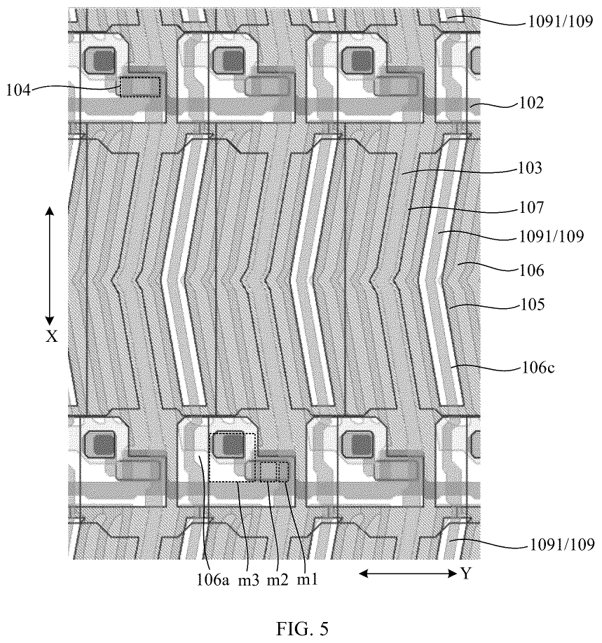

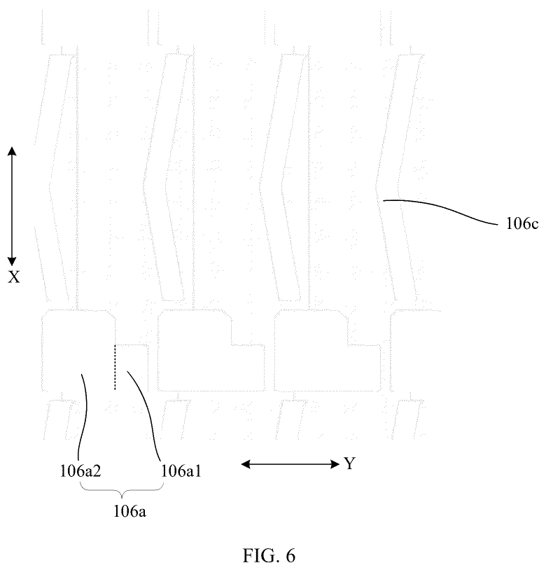

With reference to FIGS. 3 and 4, the length of the second region 106a2 in the first direction X is different from the length of the first region 106a1 in the first direction X. In the embodiments of the present disclosure, the length of the first region 106a1 in the first direction X and the length of the second region 106a2 in the first direction X can be adjusted according to actual requirements for the display panel 1. For example, in FIGS. 3 and 4, the length of the first region 106a1 in the first direction X is greater than the length of the second region 106a2 in the first direction X. Alternatively, FIG. 5 is a schematic partial diagram of a display panel according to some embodiments of the present disclosure, and FIG. 6 is a schematic diagram of a common electrode in the display panel shown in FIG. 5. Referring to FIG. 6, the length of the second region 106a2 in the first direction X is greater than the length of the first region 106a1 in the first direction X.

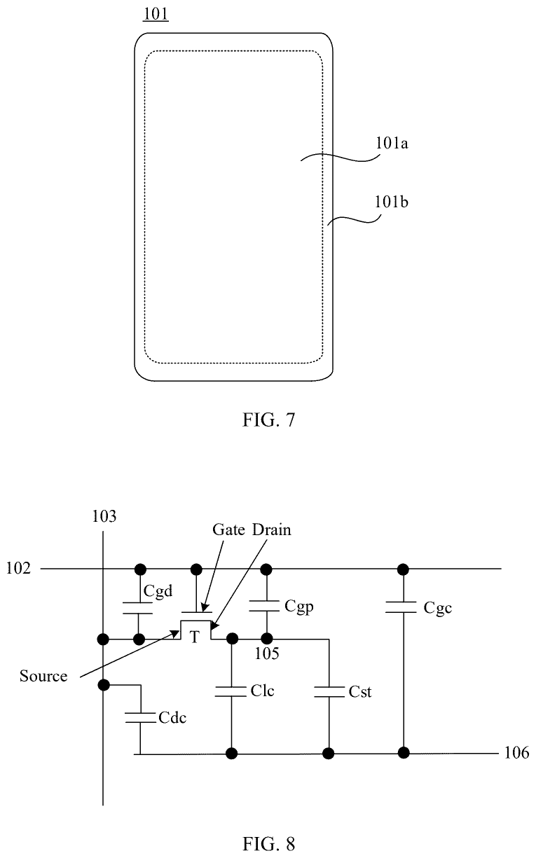

In some embodiments, referring to FIG. 7, the base substrate 101 is provided with a display region 101a and a peripheral region 101b surrounding the display region 101a. The display panel 1 further includes a common driving power circuit (not shown in the figure) disposed in the peripheral region 101b. The common driving power circuit is connected to the common electrode 106 and used to provide a common signal to the common electrode 106. And, the part of the common electrode 106 disposed in the peripheral region 101b is connected to the common drive power circuit.

Referring to FIGS. 1 and 2, the display panel 1 further includes multiple third signal traces 108 arrayed along the first direction X and extending along the second direction Y. Each third signal trace 108 is connected to the common electrode 106. Moreover, each of the third signal traces 108 is also connected to the common driving power circuit. In this way, besides being directly connected to the common driving power circuit, the common electrode 106 is also indirectly connected to the common driving power circuit via the third signal traces 108, thereby reducing the voltage drop (Loading) of the common signals of the common electrodes 106 in different regions, improving the uniformity of the common signals transmitted from different regions of the common electrodes 106, and ensuring the display uniformity of the display panel 1.

Referring to FIGS. 1 and 2, the orthographic projection of the first opening 106a on the base substrate 101 covers a target overlapping region n. The target overlapping region n is an overlapping region between the orthographic projection of the third signal trace 108 on the base substrate 101 and the orthographic projection of the second signal trace 103 on the base substrate 101.

By making the orthographic projection of the first opening 106a on the base substrate 101 cover the target overlapping region n, the coupling capacitance between the common electrode 106 and the second signal trace 103 and the third signal trace 108 in the target overlapping region n is avoided, thereby avoiding the coupling capacitance in the target overlapping region n from being too large. This further avoids the overheating of the display panel 1 and ensures the yield of the display panel 1.

Referring to FIG. 5, the display panel 1 further includes multiple fourth signal traces 109 arranged along the second direction Y and extending along the first direction X. Each of the fourth signal traces 109 is connected to the common electrode 106. The connection between the fourth signal trace 109 and the common electrode 106 is not shown in FIG. 5.

In some embodiments, each of the fourth signal traces 109 extending along the first direction X are divided into multiple second signal line segments 1091 by the multiple first signal traces 102 extending along the first direction X. The common electrode 106 is provided with multiple third openings 106c. An orthographic projection of each third opening 106c on the base substrate 101 covers an orthographic projection of one second signal line segment 1091 on the base substrate. That is, the common electrode 106 is provided with multiple third openings 106c corresponding to each fourth signal trace 109, the multiple third openings 106c are arranged along an extension direction X of the fourth signal trace 109 with gaps between adjacent third openings 106c.

Referring to FIG. 6, in the case that the common electrode 106 is provided with the multiple third openings 106c, each of the third openings 106c may be disposed between two first openings 106a adjacent in the first direction X, and there is a gap between the third opening 106c and the adjacent first openings 106a in the first direction X. That is, a row of first openings 106a and a row of third openings 106c are staggered in the first direction X and have gaps between each other. This not only reduces the coupling capacitance, but also ensures that the common electrode 106 is in a connected state at the gaps between the first opening 106a and the third opening 106c, which facilitates signal conduction of the common electrode 106 as a whole.

Since the orthographic projection of the common electrode 106 on the base substrate 101 does not overlap the orthographic projection of the signal line segments of the fourth signal trace 109 on the base substrate 101, the projection overlapping region between the common electrode 106 and the fourth signal trace 109 is reduced, thereby reducing the coupling capacitance between the common electrode 106 and the fourth signal trace 109. The coupling capacitance of the display panel 1 is reduced in a whole. This further avoids the overheating of the display panel 1 and ensures the yield of the display panel 1.

Referring to FIG. 5, the orthographic projection of the second signal line segment 1091 of the fourth signal trace 109 on the base substrate 101 overlaps the orthographic projection of the light-transmitting region on the base substrate 101, so that the orthographic projection of the third opening 106c of the common electrode 106 on the base substrate 101 overlaps the orthographic projection of the light-transmitting region on the base substrate 101. Further, since the light-transmitting region is required to achieve a light transmission effect, the orthographic projection of the black matrix layer 107 on the base substrate 101 will not cover the light-transmitting region. As a result, the orthographic projection of the third opening 106c on the base substrate 101 lies outside the orthographic projection of the black matrix layer 107 on the base substrate 101.

Typically, the fourth signal trace 109 is a touch trace contained in the touch structure in the display panel 1, and the touch trace is not affected by the uncontrollable electric field generated between the signal traces and the pixel electrodes 105. Therefore, even though the third opening 106c is not covered by the black matrix layer 107 (resulting in the inability to achieve shading) and the third opening 106c of the common electrode 106 is a hollow area without the common electrode material (resulting in the inability to shield the electric field), the part of the display panel 1 corresponding to the third opening 106c is not affected by the uncontrollable electric field to cause light leakage.

In the implementation shown in FIG. 5, the orthographic projection of the first opening 106a of the common electrode 106 on the base substrate 101 partially overlaps the orthographic projection of the first signal trace 102 on the base substrate 101, in addition to covering the connection positions. Therefore, the projection overlapping region between the common electrode 106 and the first signal trace 102 is reduced, thereby reducing the coupling capacitance between the common electrode 106 and the first signal trace 102.

In some embodiments, the row of first openings 106a arranged along the second direction Y in FIG. 5 all expose a part of the first signal trace 102. Moreover, gaps are arranged between the adjacent first openings 106a along the second direction Y to ensure the signal conduction of the common electrode 106 as a whole.

FIG. 8 is a schematic diagram of a connection relationship of a pixel circuit according to some embodiments of the present disclosure. Referring to FIG. 8, the pixel circuit 104 may include a switching transistor T. The switching transistor T includes a gate, a source, and a drain. The gate of the switching transistor T is connected to the first signal trace 102, and the switching transistor T is turned on or off under the control of a gate signal provided by the first signal trace 102. The source of the switch transistor T is connected to the second signal trace 103, and the drain of the switch transistor T is connected to the pixel electrode 105. In the case that the switching transistor T is in on-state, the second signal trace 103 transmits the data driving signal to the pixel electrode 105 via the switching transistor T, which causes a change in the electric field between the pixel electrode 105 and the common electrode 106, thereby driving the liquid crystal molecules in the liquid crystal layer to be deflected, realizing the light transmittance.

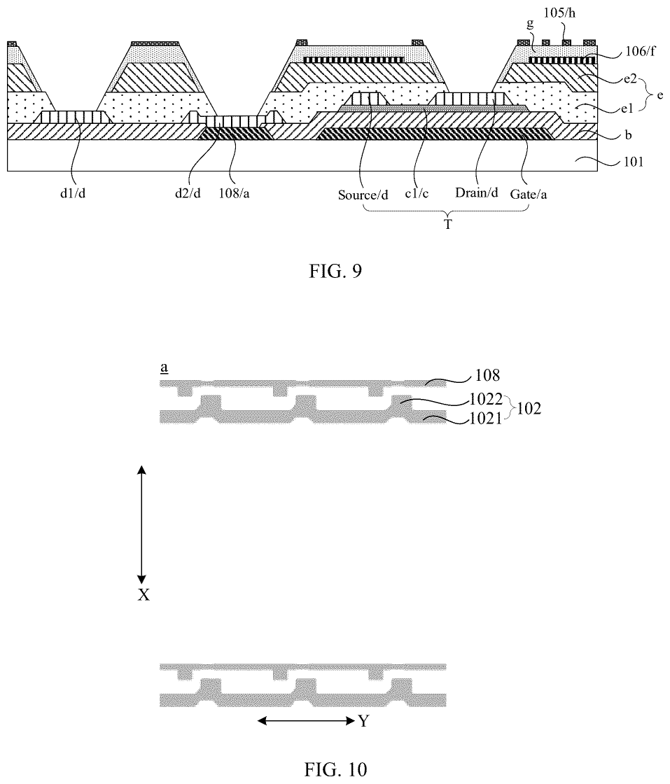

FIG. 9 is a partial cross-sectional view of a display panel according to some embodiments of the present disclosure. Referring to FIG. 9, the display panel 1 includes a gate layer a, a first insulating layer b, an active layer c, a source-drain layer d, a second insulating layer e, a common electrode layer f, a third insulating layer g, and a pixel electrode layer h stacked sequentially in a direction away from the base substrate 101.

In a first optional implementation, in the case where the common electrode 106 includes multiple first openings 106a and the display panel 1 includes multiple third signal traces 108 (i.e., the scenario of FIG. 1). To describe the film layers clearly, the film layers are briefly described below in a step-by-step stacked layers.

FIG. 10 is a partial top view of a gate layer according to some embodiments of the present disclosure. Referring to FIG. 10, the gate layer a includes multiple first signal traces 102 and multiple third signal traces 108. The multiple first signal traces 102 and the multiple third signal traces 108 are staggered in the first direction X.

Each of the multiple first signal traces 102 includes a signal trace body 1021 and a signal trace pattern 1022 that are in a one-piece structure. The first signal trace 102 extending along the second direction Y may mean that the signal trace body 1021 extends along the second direction Y and the signal trace pattern 1022 is a raised pattern formed on a side of the signal trace body 1021. The signal trace pattern 1022 may serve as the gate of the switching transistor T.

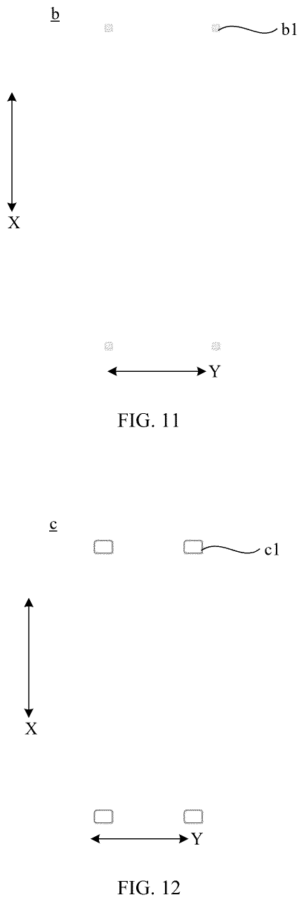

The first insulating layer b may be formed on the gate layer a described above, and the first insulating layer b is used to insulate the gate layer a from the active layer c subsequently formed. The first insulating layer b may be a gate insulator (GI). Referring to FIG. 11, the first insulating layer b is provided with first via holes b1, and the first via holes b1 are used for connecting the third signal trace 108 to the common electrode 106. In order to illustrate the first via holes b1 in the first insulating layer b clearly, filled patterns are used to represent the first via holes b1 in FIG. 11, and other areas not filled with patterns represent areas where the first insulating layer b has a solid material.

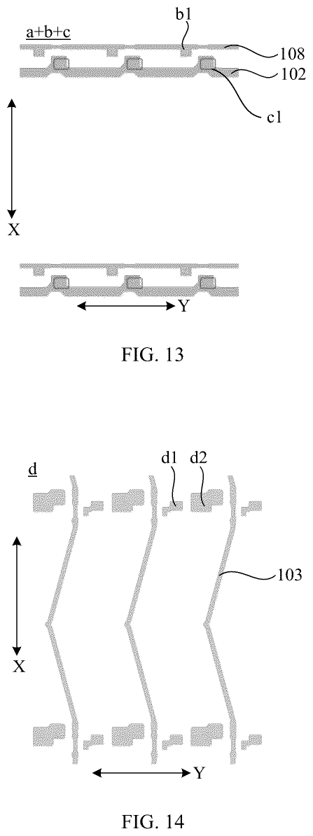

FIG. 12 is a partial top view of an active layer according to some embodiments of the present disclosure. FIG. 13 is a schematic partial diagram of a lamination of a gate layer, a first insulating layer, and an active layer according to some embodiments of the present disclosure. Referring to FIGS. 12 and 13, the active layer c includes multiple active patterns c1, and each switching transistor T includes one active pattern c1.

The orthographic projection of each active pattern c1 on the base substrate 101 includes a channel region and a doped area (source region and drain region), and the source region and drain region may be conductive by doping to achieve electrical connection to the structures. The channel region is disposed between the source region and drain region, and the channel region is an area where the signal trace pattern 1022 overlaps the active pattern c1 and does not overlap either the source region or drain region.

The active layer c may be made of amorphous silicon, polycrystalline silicon, oxide semiconductor material, and the like. It should be noted that the source region and the drain region described above may be regions doped with n-type impurities or p-type impurities.

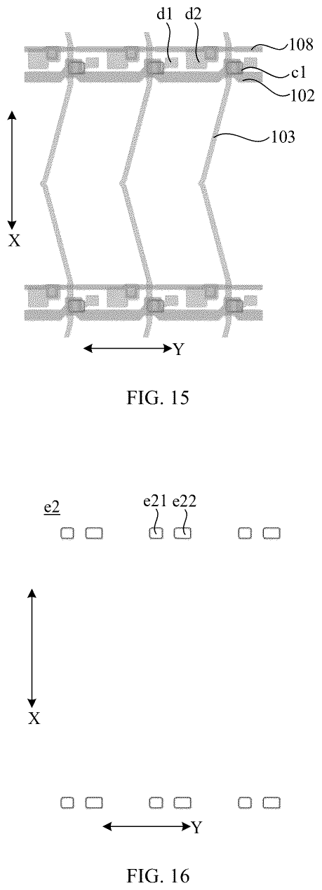

FIG. 14 is a partial top view of a source-drain layer according to some embodiments of the present disclosure. FIG. 15 is a schematic partial diagram of a lamination of a gate layer, a first insulating layer, an active layer, and a source-drain layer according to some embodiments of the present disclosure. Referring to FIGS. 14 and 15, the source-drain layer d includes a second signal trace 103 arranged along the second direction Y with gaps, a first connection portion d1, and a second connection portion d2.

A target portion of the second signal trace 103 is connected to the active pattern c1, and each second signal trace 103 may have multiple target portions, each target portion being connected to one active pattern c1 corresponding to the target portion. One end of the first connection portion d1 is connected to the active pattern c1. The target portion of the second signal trace 103 serves as the source of the switching transistor T, and the part of the first connection portion d1 that overlaps and is connected to the drain region serves as the drain of the switching transistor T.

In addition, the orthographic projection of the second connection portion d2 on the base substrate 101 overlaps the orthographic projection of the third signal trace 108 on the base substrate 101, the orthographic projection of the first via hole b1 in the first insulating layer b on the base substrate 101 is located in the projection overlapping region of the second connection portion d2 and the third signal trace 108 on the base substrate 101, and the second connection portion d2 is connected to the third signal trace 108 through the first via hole b1 in the first insulating layer b.

The second insulating layer e may be formed on the source-drain layer d, and the second insulating layer e is used to insulate the source-drain layer d from the common electrode 106 subsequently formed. The second insulating layer e may include a first passivation layer (PVX) e1 and a planarization layer (PLN) e2 stacked in the direction away from the base substrate 101. The planarization layer e2 may be made of an organic material, such as a resin.

The first passivation layer e1 may be provided with a second via hole e11 and a third via hole e12. An orthographic projection of the second via hole e11 on the base substrate 101 does not overlap the orthographic projection of the common electrode 106 on the base substrate 101, and the second via hole e11 is used for connecting the pixel electrode 105 in the pixel electrode layer h subsequently formed to the first connection portion d1 in the source-drain layer d. An orthographic projection of the third via hole e12 on the base substrate 101 does not overlap the orthographic projection of the common electrode 106 on the base substrate 101 and partially overlaps the orthographic projection of the second connection portion d2 in the source-drain layer d on the base substrate 101. The third via hole e12 is used for connecting the third connection portion h1 in the pixel electrode layer h subsequently formed and the second connection portion d2 in the source-drain layer d.

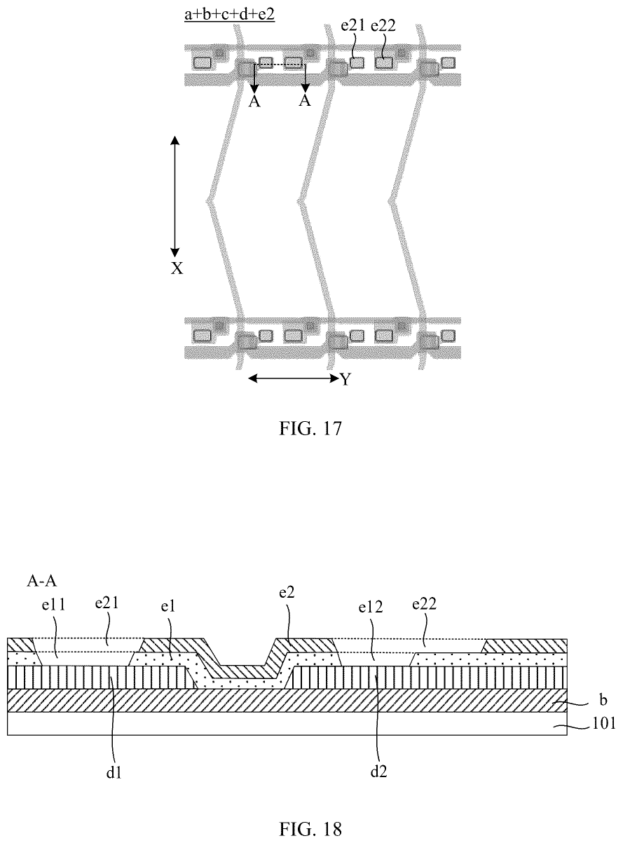

FIG. 16 is a schematic diagram of a planarization layer according to some embodiments of the present disclosure. FIG. 17 is a schematic partial diagram of a lamination of a gate layer, a first insulating layer, an active layer, a source-drain layer, and a planarization layer according to some embodiments of the present disclosure. Referring to FIGS. 16 and 17, the planarization layer e2 may be provided with a fourth via hole e21 and a fifth via hole e22.

FIG. 18 is a sectional view in the direction A-A in FIG. 17. In combination with FIGS. 16 to 18, an orthographic projection of the fourth via hole e21 in the planarization layer e2 on the base substrate 101 partially overlaps the orthographic projection of the second via hole e11 in the first passivation layer e1 on the base substrate 101, and the fourth via hole e21 is used for connecting the pixel electrodes 105 subsequently formed to the first connection portion d1. An orthographic projection of the fifth via hole e22 of the planarization layer e2 on the base substrate 101 partially overlaps the orthographic projection of the third via hole e12 of the first passivation layer e1 on the base substrate 101, and the fifth via hole e22 also has the orthographic projection that does not overlap the orthographic projection of the third via hole e12 in the first passivation layer e1. That is, the orthographic projection of the fifth via hole e22 on the base substrate 101 overlaps the orthographic projection of the third via hole e12 on the base substrate 101, and the fifth via hole e22 covers the third via hole e12.

In order to illustrate the fourth via hole e21 and fifth via hole e22 in the planarization layer e2 clearly, filled patterns are used to represent the via holes in FIGS. 16 to 17, and other areas not filled with patterns represent areas where the planarization layer e2 has a solid material.

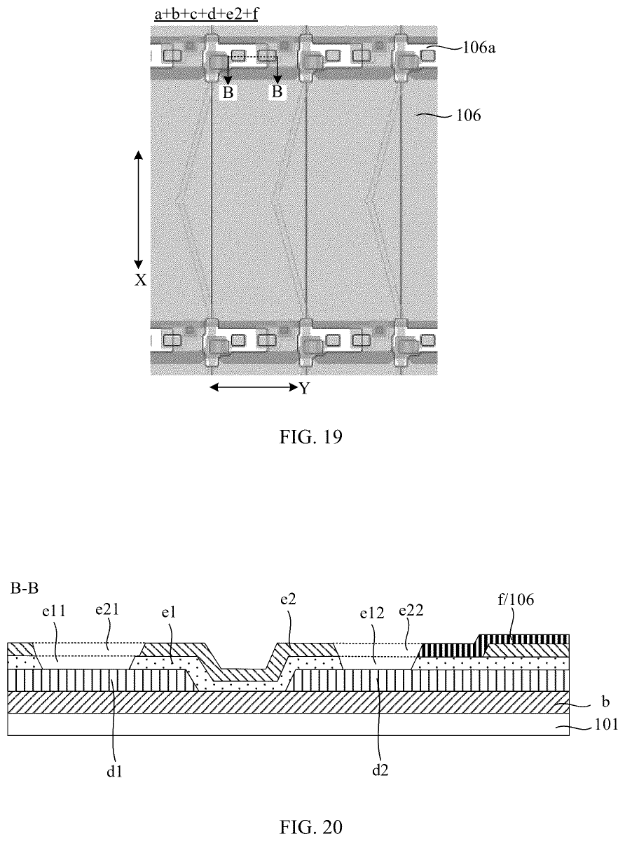

FIG. 19 is a schematic partial diagram of a lamination of a gate layer, a first insulating layer, an active layer, a source-drain layer, a planarization layer, and a common electrode layer according to some embodiments of the present disclosure. The common electrode layer as shown in FIG. 19 includes a common electrode shown in FIG. 3. FIG. 20 is a sectional view in a direction B-B in FIG. 19.

Referring to FIG. 3, FIG. 19 and FIG. 20, the orthographic projection of the common electrode 106 on the base substrate 101 partially overlaps the orthographic projection of the fifth via hole e22 of the planarization layer e2 on the base substrate 101. The orthographic projection of the first opening 106a in the common electrode 106 on the base substrate 101 overlaps the orthographic projection of the third via hole e12 in the first passivation layer e1 on the base substrate 101.

That is, the common electrode 106 is arranged on the planarization layer e2 where the fifth via hole e22 does not overlap the third via hole e12. The first opening 106a of the common electrode 106 is arranged on the planarization layer e2 where the fifth via hole e22 overlaps the third via hole e12.

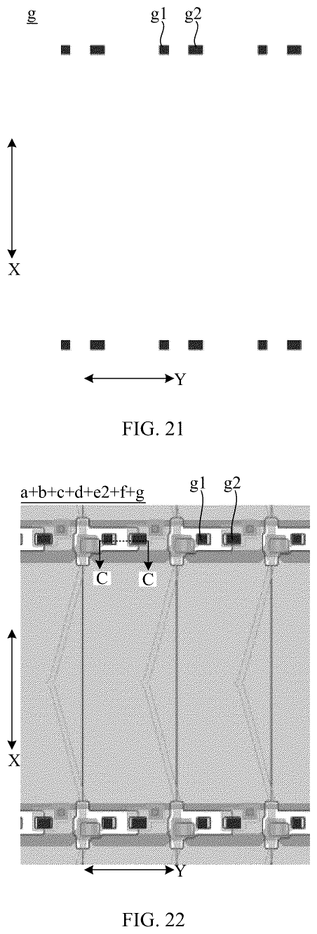

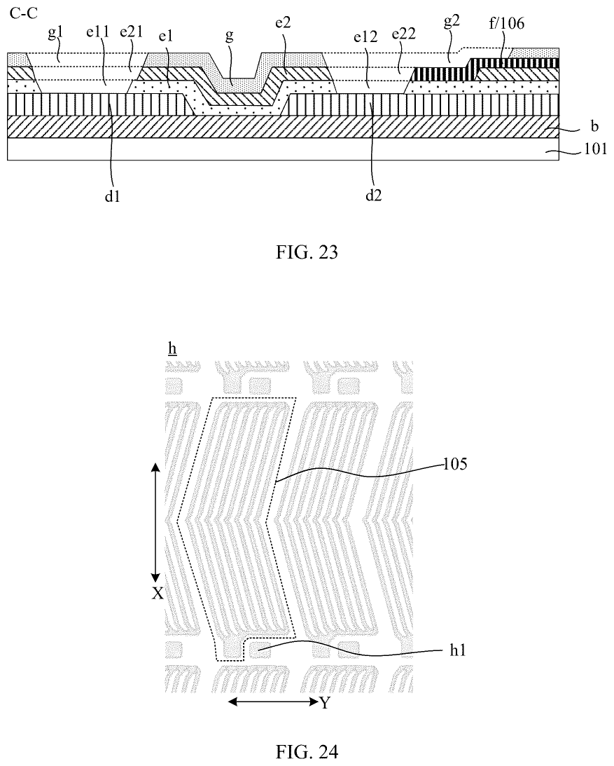

FIG. 21 is a partial top view of a third insulating layer according to some embodiments of the present disclosure. FIG. 22 is a schematic partial diagram of a lamination of a gate layer, a first insulating layer, an active layer, a source-drain layer, a planarization layer, a common electrode layer, and a third insulating layer according to some embodiments of the present disclosure. FIG. 23 is a sectional view in a direction C-C in FIG. 19. In combination with FIGS. 21 to 22, the third insulating layer g may be a second passivation layer, and the third insulating layer g includes a sixth via hole g1 and a seventh via hole g2.

An orthographic projection of the sixth via hole g1 on the base substrate 101 overlaps the orthographic projection of the first connection portion d1 on the base substrate. The sixth via hole g1 is used for connecting the pixel electrode 105 in the pixel electrode layer h formed subsequently to the first connection portion d1 in the source-drain layer d. That is, the pixel electrode 105 is connected to the first connection portion d1 through the second via hole e11 in the passivation layer, the fourth via hole e21 in the planarization layer e2, and the sixth via hole g1 in the third insulating layer g.

The orthographic projection of the seventh via hole g2 on the base substrate 101 partially overlaps the orthographic projection of the first opening 106a on the base substrate 101, and partially overlaps the orthographic projection of the common electrode 106 on the base substrate 101. That is, a part of the seventh via hole g2 may expose a part of the second connection portion d2 disposed in the source-drain layer d, and another part of the seventh via hole g2 may expose a part of the common electrode 106.

In order to illustrate the sixth via hole g1 and seventh via hole g2 in the third insulating layer g clearly, filled patterns are used to represent the via holes in FIGS. 21 to 22, and other areas not filled with patterns represent areas where the third insulating layer g has a solid material.

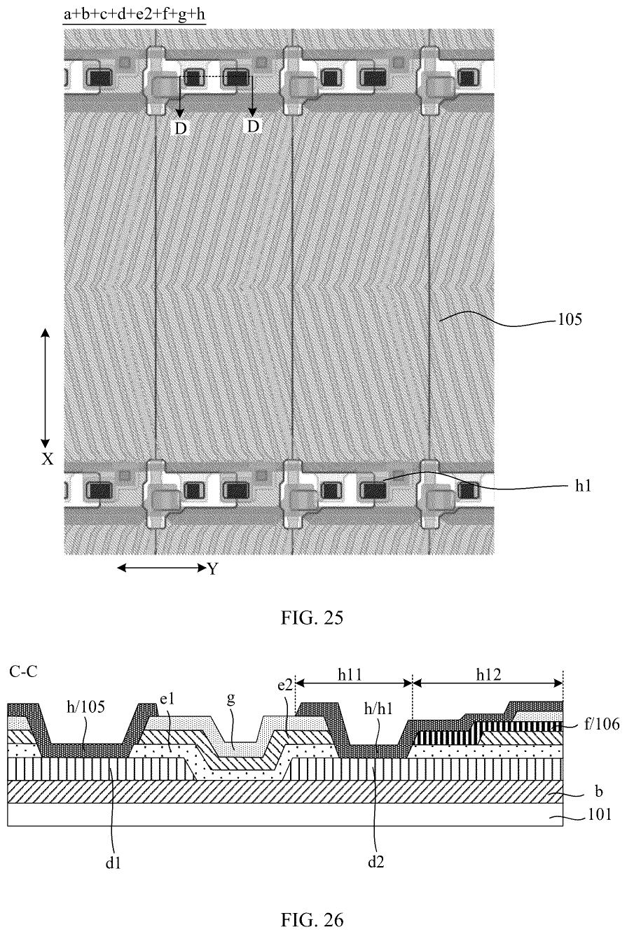

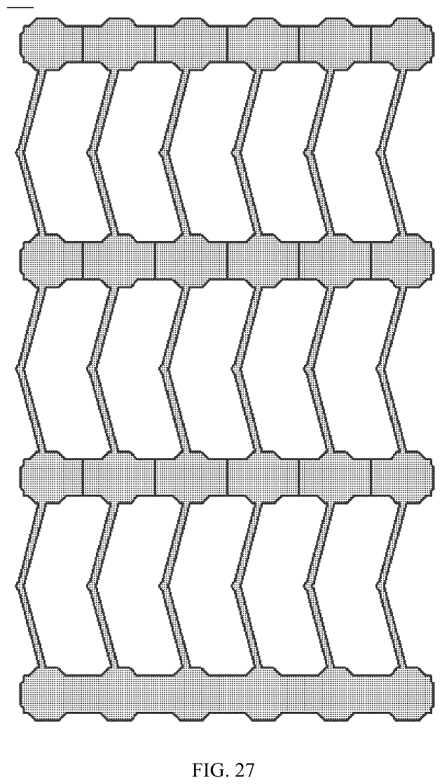

FIG. 24 is a partial top view of a pixel electrode layer according to some embodiments of the present disclosure. FIG. 25 is a schematic partial diagram of a lamination of a gate layer, a first insulating layer, an active layer, a source-drain layer, a planarization layer, a common electrode layer, a third insulating layer, and a pixel electrode layer according to some embodiments of the present disclosure. FIG. 26 is a sectional view in a direction D-D in FIG. 25.

In combination with FIGS. 24 to 26, the pixel electrode layer h includes a pixel electrode 105 and a third connection portion h1. An orthographic projection of the pixel electrode 105 on the base substrate 101 partially overlaps the orthographic projection of the first connection portion d1 on the base substrate 101, and the pixel electrode 105 is connected to the first connection portion d1, which allows the second signal trace 103 to transmit a data driving signal to the pixel electrode 105 via the pixel circuit 104.

The orthographic projection of the third connection portion h1 on the base substrate 101 includes a first projection region h11 and a second projection region h12. The first projection region h11 overlaps the orthographic projection of the first opening 106a on the base substrate 101, and the second projection region h12 overlaps the orthographic projection of the common electrode 106 on the base substrate 101. The part of the third connection portion h1 located in the first projection region h11 is connected to the second connection portion d2, and the part of the third connection portion h1 located in the second projection region h12 is connected to the common electrode 106, which realizes that the third signal trace 108 is connected to the common electrode 106 via the second connection portion d2 and the third connection portion h1.

FIG. 27 is a schematic diagram of a black matrix layer in the display panel shown in FIG. 1. In combination with FIG. 1 and FIG. 27, the black matrix layer 107 covers the first opening 106a of the common electrode 106 and also covers the second signal trace 103. In this way, lights emitted from the first opening 106a or the second signal trace 103 are covered by the black matrix layer 107, avoiding the light leakage in the display panel 1 at the first opening 106a or the second signal trace 103 and ensuring the display effect of the display panel 1.

As a second optional implementation, in the case where the common electrode 106 includes multiple first openings 106a and multiple second openings 106b, and where the display panel 1 includes multiple third signal traces 108 (i.e., the scenario of FIG. 2). To describe the film layers clearly, the film layers are briefly described below in a step-by-step stacked layer.

In some embodiments of the present disclosure, the gate layer a, the first insulating layer b, the active layer c, and the second insulating layer e may be referred to the description of the first optional implementation described above, which will not be repeated herein.

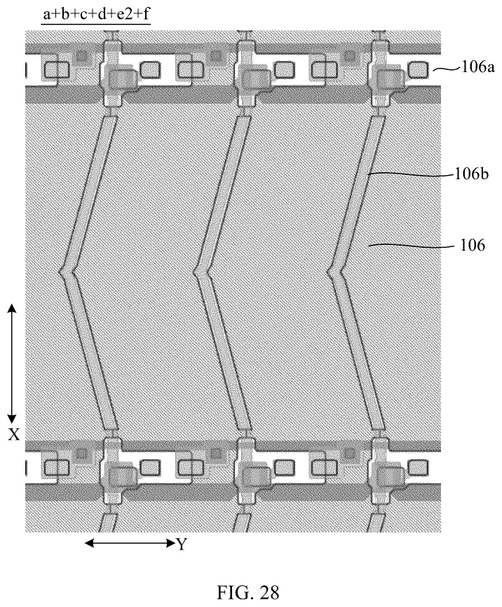

FIG. 28 is a schematic partial diagram of a lamination of a gate layer, a first insulating layer, an active layer, a source-drain layer, a planarization layer, and a common electrode layer according to some embodiments of the present disclosure. The common electrode 106 contained in the common electrode layer f shown in FIG. 28 is the common electrode shown in FIG. 4. Referring to FIG. 4 and FIG. 28, the common electrode 106 includes multiple second openings 106b in addition to multiple first openings 106a.

The orthographic projection of each second open area 106b on the base substrate 101 covers a part of the orthographic projection of one second signal trace 103 on the base substrate 101.

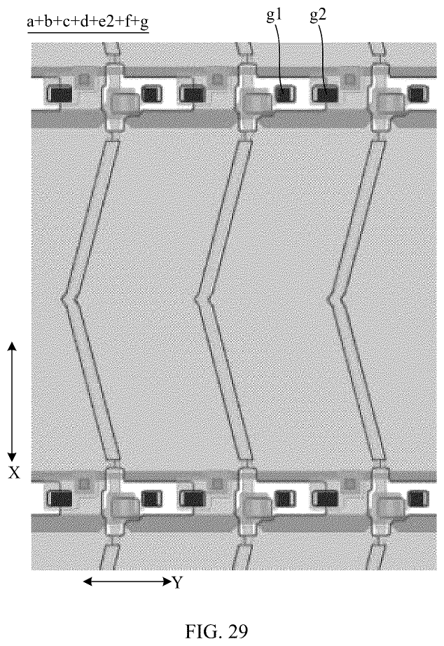

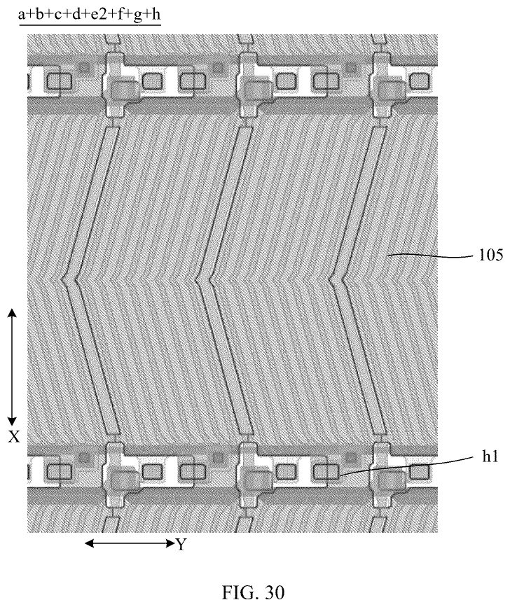

FIG. 29 is a schematic partial diagram of a lamination of a gate layer, a first insulating layer, an active layer, a source-drain layer, a planarization layer, a common electrode layer, and a third insulating layer according to some embodiments of the present disclosure. FIG. 30 is a schematic partial diagram of a lamination of a gate layer, a first insulating layer, an active layer, a source-drain layer, a planarization layer, a common electrode layer, a third insulating layer, and a pixel electrode layer according to some embodiments of the present disclosure. Referring to FIGS. 29 and 30, the third insulating layer g and the pixel electrode layer h may be identical to those in the first optional implementation.

In the second optional implementation, the structure of the black matrix layer 107 may be identical to the structure of the black matrix layer 107 in the first optional implementation, such as the black matrix layer 107 shown in FIG. 27. Since the black matrix layer 107 covers the second signal trace 103, even if the common electrode 106 is provided with the second opening 106b corresponding to the second signal trace 103, the light transmitted from the second opening 106b is covered by the black matrix layer 107, avoiding the light leakage in the display panel 1 at the second opening 106b, and ensuring the display effect of the display panel 1.

As a third optional implementation, in the case where the common electrode 106 includes multiple first openings 106a and multiple third openings 106c, and where the display panel 1 includes multiple fourth signal traces 109 (i.e., the scenario of FIG. 5). To describe the film layers clearly, the film layers are briefly described below in a step-by-step stacked layer.

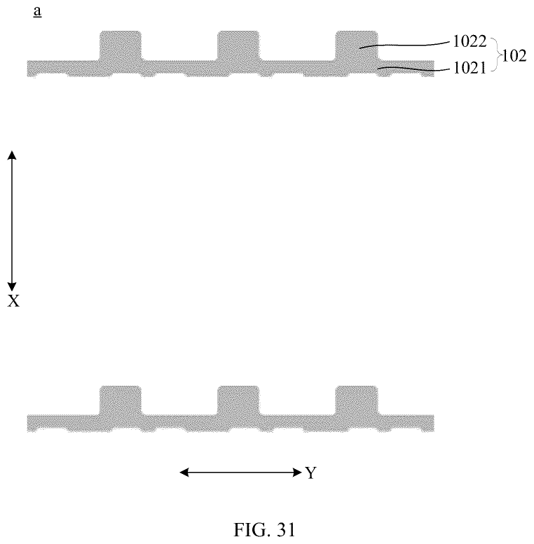

FIG. 31 is a partial top view of a gate layer according to some embodiments of the present disclosure. Referring to FIG. 31, the gate layer a includes multiple first signal traces 102. and the multiple first signal traces 102 are arranged along the first direction X and extend along a second direction Y.

Each of the first signal traces 102 includes a signal trace body 1021 and a signal trace pattern 1022 that are in a one-piece structure. The first signal trace 102 extending along the second direction Y may mean that the signal trace body 1021 extends along the second direction Y, and the signal trace pattern 1022 is a raised pattern formed on a side of the signal trace body 1021. The signal trace pattern 1022 may serve as the gate of the switching transistor T.

The first insulating layer b may be formed on the gate layer a described above, and the first insulating layer b is used for connecting the gate layer a to the active layer c subsequently formed. The first insulating layer b is a gate insulating layer, which may be an entire layer, and therefore is no longer schematized herein by way of the accompanying drawings.

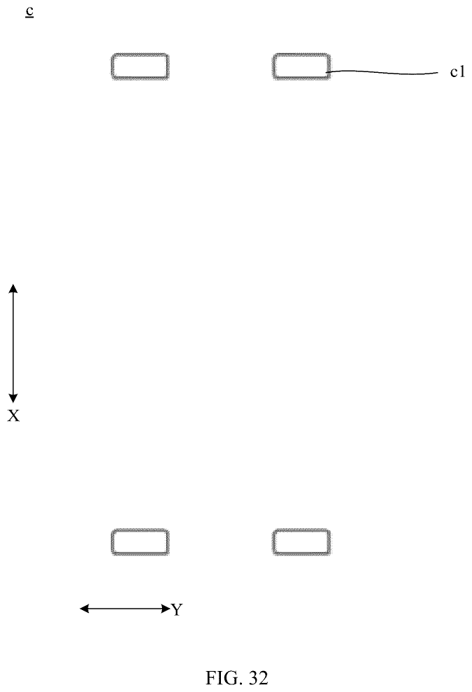

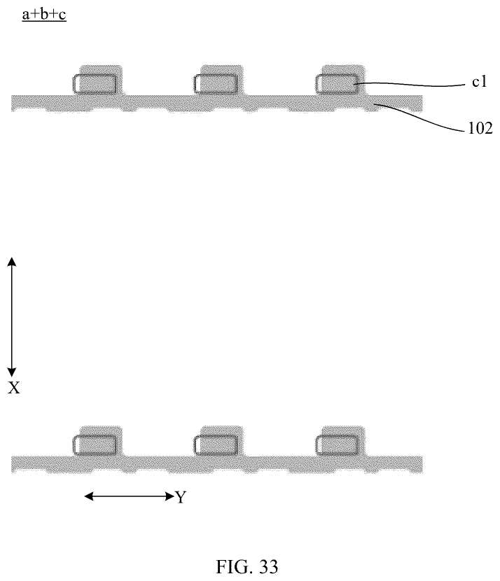

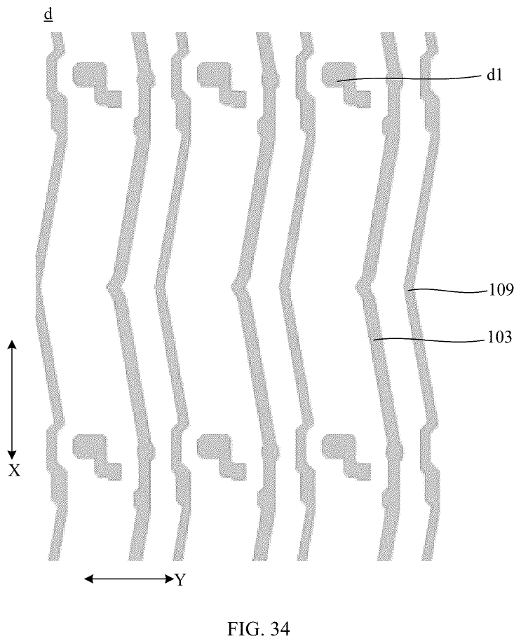

FIG. 32 is a partial top view of an active layer according to some embodiments of the present disclosure. FIG. 33 is a schematic partial diagram of a lamination of a gate layer, a first insulating layer, and an active layer according to some embodiments of the present disclosure. Referring to FIGS. 32 and 33, the active layer c includes multiple active patterns c1 and each switching transistor T includes one active pattern c1.

The orthographic projection of each active pattern c1 on the base substrate 101 includes a channel region and a doped area (source region and drain region), and the source region and drain region may be conductive by doping to achieve electrical connection to the structures. The channel region is disposed between the source region and drain region, and the channel region is a region where the signal trace pattern 1022 overlaps the active pattern c1 and does not overlap either the source region or drain region.

The active layer c may be made of amorphous silicon, polycrystalline silicon, oxide semiconductor material, and the like. It should be noted that the source region and the drain region described above may be regions doped with n-type impurities or p-type impurities.

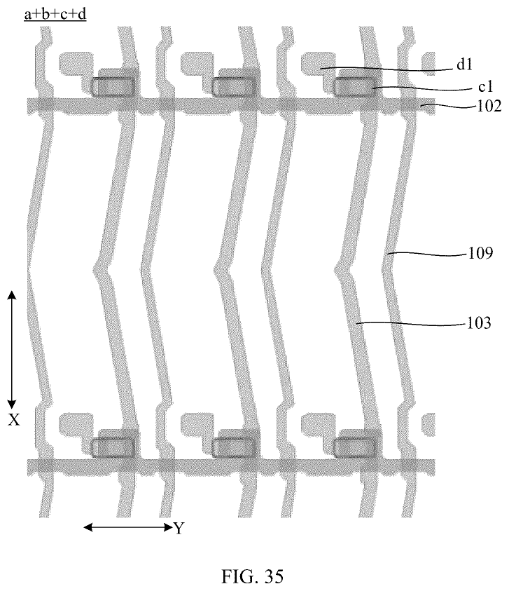

FIG. 34 is a partial top view of a source-drain layer according to some embodiments of the present disclosure. FIG. 35 is a schematic partial diagram of a lamination of a gate layer, a first insulating layer, an active layer, and a source-drain layer according to some embodiments of the present disclosure. Referring to FIGS. 34 and 35, the source-drain layer d includes a second signal trace 103 arranged along the second direction Y with gaps, a fourth signal trace 109, and a first connection portion d1.

A target portion of the second signal trace 103 is connected to the active pattern c1, and each second signal trace 103 may have multiple target portions, each target portion being connected to one active pattern c1 corresponding to the target portion. One end of the first connection portion d1 is connected to the active pattern c1. The target portion of the second signal trace 103 serves as the source of the switching transistor T, and the part of the first connection portion d1 that overlaps and connects with the drain region serves as the drain of the switching transistor T.

In addition, the fourth signal trace 109 may be used for connecting to the common electrode 106 in the common electrode layer f subsequently formed, to provide a common signal for the common electrode 106.

The second insulating layer e may be formed on the source-drain layer d, and the second insulating layer e is used to insulate the source-drain layer d from the common electrode 106 subsequently formed. Wherein, the second insulating layer e may include a first passivation layer e1 and a planarization layer e2 stacked in the direction away from the base substrate 101. In the implementation, the via holes in the first passivation layer e1 are identical to the via holes in the planarization layer e2.

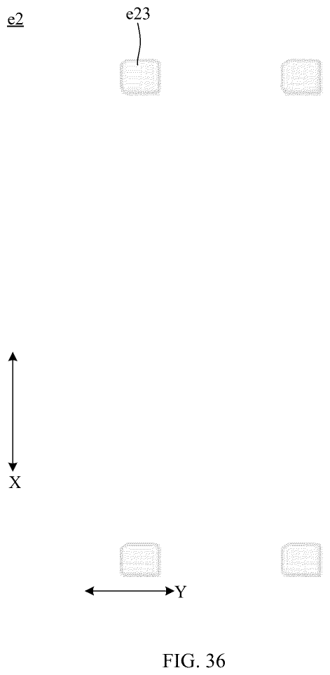

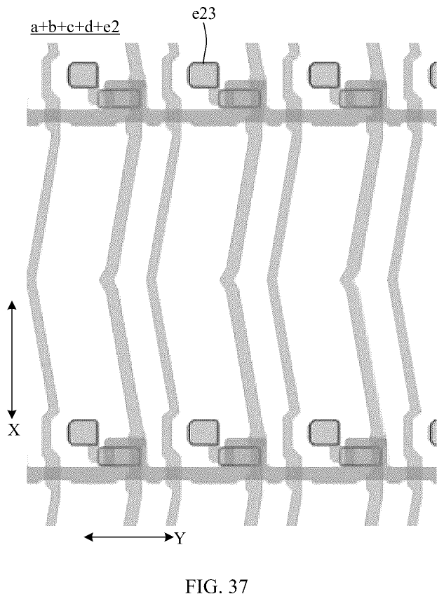

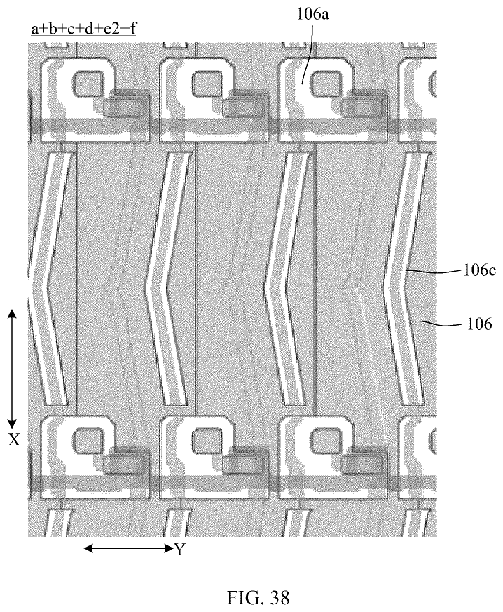

Referring to FIGS. 36 and 37, the planarization layer e2 is taken as an example, the first passivation layer e1 and the planarization layer e2 may have an eighth via hole e23. An orthographic projection of the eighth via hole e23 on the base substrate 101 partially overlaps the orthographic projection of the first connection portion d1 on the base substrate 101. The eighth via hole e23 is used for connecting the pixel electrode 105 in the pixel electrode layer h formed subsequently to the first connection portion d1 in the source-drain layer d.

In order to illustrate the eighth via holes e23 in the first passivation layer e1 and the planarization layer e2 clearly, filled patterns are used to represent the via holes b1 in FIGS. 36 to 37, and other areas not filled with patterns represent areas where the planarization layer e2 has a solid material.

FIG. 38 is a schematic partial diagram of a lamination of a gate layer, a first insulating layer, an active layer, a source-drain layer, a planarization layer, and a common electrode layer according to some embodiments of the present disclosure. The common electrode 106 in the common electrode layer f shown in FIG. 38 is the common electrode shown in FIG. 6. Referring to FIG. 6 and FIG. 38, the common electrode 106 is provided with multiple first openings 106a and multiple third openings 106c.

The orthographic projection of the first opening 106a on the base substrate 101 overlaps the orthographic projection of the eighth via hole e23 on the base substrate 101, which allows the pixel electrode 105 subsequently formed to be connected to the first connection portion d1 through the eighth via hole e23 exposed by the first opening 106a. Moreover, the orthographic projection of the third opening 106c on the base substrate 101 partially overlaps the orthographic projection of the fourth signal trace 109 on the base substrate 101, which reduces the projection overlapping region between the common electrode 106 and the fourth signal trace 109, thereby reducing the coupling capacitance between the common electrode 106 and the fourth signal trace 109, and reducing the heat generation of the display panel 1.

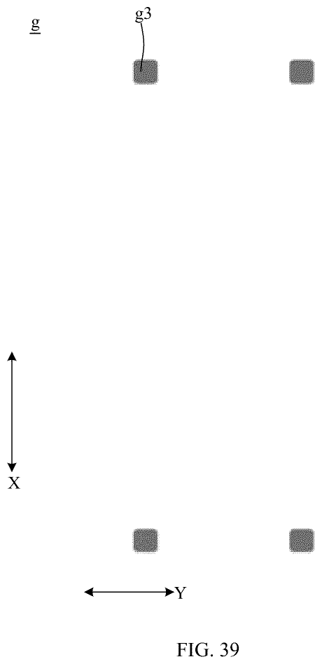

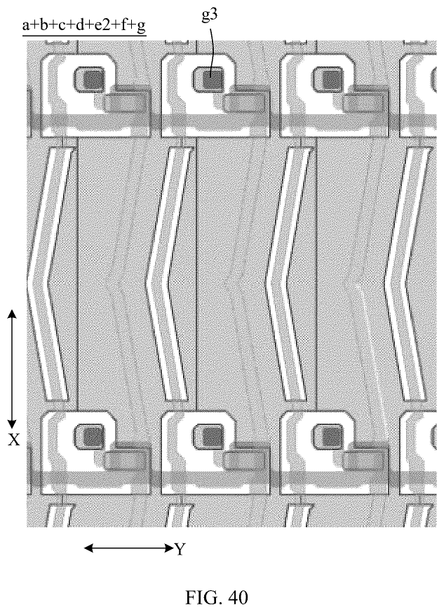

FIG. 39 is a partial top view of a third insulating layer according to some embodiments of the present disclosure. FIG. 40 is a schematic partial diagram of a lamination of a gate layer, a first insulating layer, an active layer, a source-drain layer, a planarization layer, a common electrode layer, and a third insulating layer according to some embodiments of the present disclosure. Referring to FIGS. 39 and 40, the third insulating layer g includes a ninth via hole g1.

The ninth via hole g1 is used for connecting the pixel electrode 105 in the pixel electrode layer h subsequently formed to the first connection portion d1 in the source-drain layer d. That is, the pixel electrode 105 is connected to the first connection portion d1 through the eighth via hole e23 in the second insulating layer e and the ninth via hole g1 in the third insulating layer g.

In order to illustrate the ninth via holes g1 in the third insulating layer g clearly, filled patterns are used to represent the via holes in FIGS. 39 to 40, and other areas not filled with patterns represent areas where the third insulating layer g has a solid material.

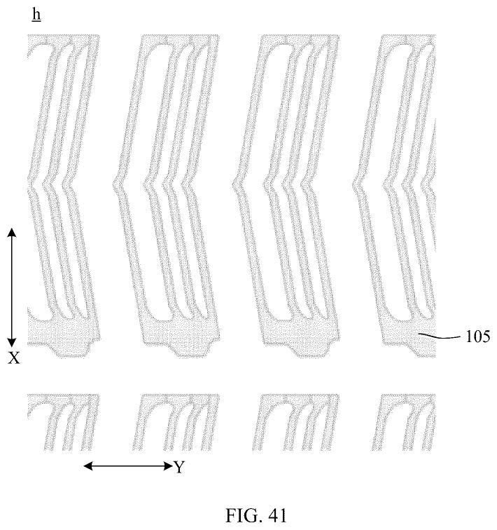

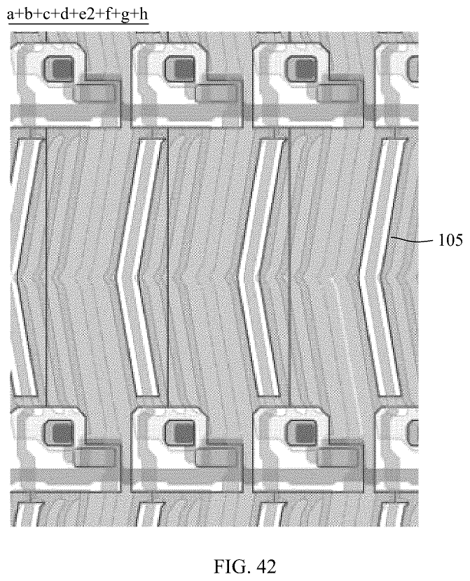

FIG. 41 is a partial top view of a pixel electrode layer according to some embodiments of the present disclosure. FIG. 42 is a schematic partial diagram of a lamination of a gate layer, a first insulating layer, an active layer, a source-drain layer, a second insulating layer, a common electrode layer, a third insulating layer, and a pixel electrode layer according to some embodiments of the present disclosure. Referring to FIGS. 41 and 42, the pixel electrode layer h includes a pixel electrode 105.

The orthographic projection of the pixel electrode 105 on the base substrate 101 partially overlaps the orthographic projection of the first connection portion d1 on the base substrate 101, and the pixel electrode 105 is connected to the first connection portion d1, which allows the second signal trace 103 to transmit a data driving signal to the pixel electrode 105 via the pixel circuit 104.

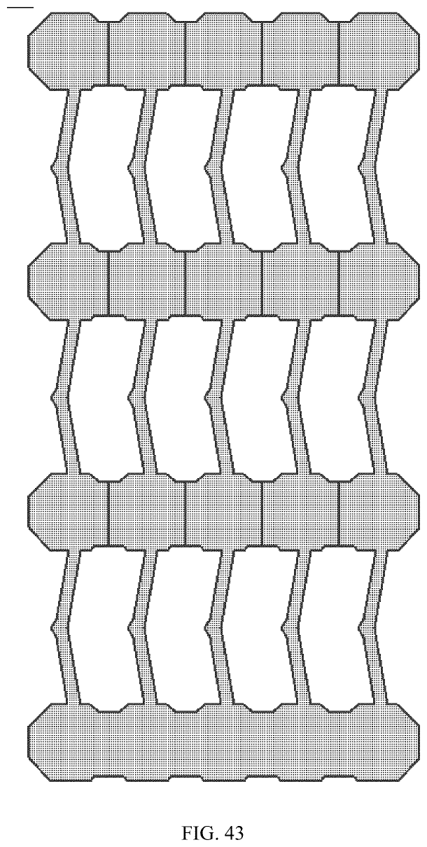

FIG. 43 is a schematic diagram of the black matrix layer in the display panel shown in FIG. 5. In combination with FIG. 5 and FIG. 43, the black matrix layer 107 covers the first opening 106a of the common electrode 106. In this way, lights emitted from the first opening 106a are covered by the black matrix layer 107, avoiding the light leakage in the display panel 1 at the first opening 106a and ensuring the display effect of the display panel 1.

Moreover, the black matrix layer 107 does not cover the third opening 106c of the common electrode 106. The fourth signal trace 109 is provided at the location where the third opening 106 is located, and the fourth signal trace 109 may be a touch trace contained in the touch structure in the display panel 1. Since the touch trace is not affected by the uncontrollable electric field generated between the signal traces and the pixel electrodes 105, even though the third opening 106c is not covered by the black matrix layer 107 (resulting in the inability to achieve shading) and the third opening 106c of the common electrode 106 is a hollow area without the common electrode material (resulting in the inability to shield the electric field), the part of the display panel 1 corresponding to the third opening 106c is not affected by the uncontrollable electric field to cause light leakage.

In the first implementation to the third implementation, the preparation process of each film layer includes: forming a thin film layer and patterning the thin film layer using a mask plate. Among them, the patterning process includes: coating a photoresist, exposing by using a mask plate, developing, etching, and removing the photoresist. For example, the process of preparing the active pattern c1 in the active layer c includes: forming the active thin film and patterning the active thin film using a mask plate of the active layer.

It should be noted that the gate layer, the first insulating layer (the first insulating layer is required to be subjected to the patterning process in the first and second optional implementations, and is not required to be subjected to the patterning process in the third optional implementation), the active layer, the source-drain layer, the first PVX1, the planarization layer, the common electrode, the second PVX2, and the pixel electrode layer of the display panel need to be patterned using the mask plate.

Wherein, the same mask plate is adopted for the first PVX1 and the second PVX2 in the patterning process. The mask plates used in the preparation process include: a gate layer mask plate, an active layer mask plate, a first insulating layer mask plate (in the first and second optional implementations), a source-drain layer mask plate, a planarization layer mask plate, a common electrode mask plate, passivation layer (PVX1 and PVX2) mask plate, and pixel electrode mask plate.

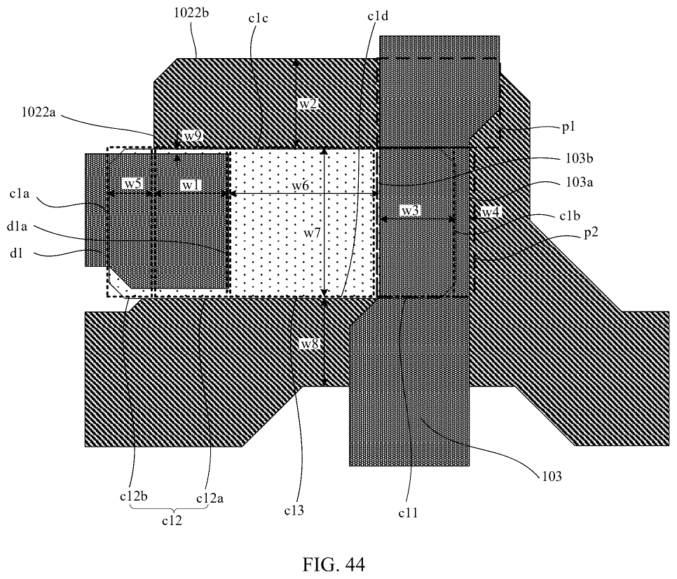

FIG. 44 is a schematic partial diagram of a gate layer, an active layer, and a source-drain layer according to some embodiments of the present disclosure. In a fourth optional implementation, referring to FIG. 44, an orthographic projection of the source region c11 on the base substrate 101 is located within the orthographic projection of the signal trace pattern 1022 on the base substrate 101. The source region c11 is an overlapping region between the orthographic projection of the active pattern c1 on the base substrate 101 and the orthographic projection of the second signal trace 103 on the base substrate 101. That is, the overlapping region between the orthographic projection of the active pattern c1 on the base substrate 101 and the orthographic projection of the second signal trace 103 on the base substrate 101 is located within the orthographic projection of the signal trace pattern 1022 on the base substrate 101.

The orthographic projection of the drain region c12 on the base substrate 101 includes: a third projection region c12a located within the orthographic projection of the signal trace pattern 1022 on the base substrate 101, and a fourth projection region c12b located outside the orthographic projection of the signal trace pattern 1022 on the base substrate 101. The drain region c12 is an overlapping region between the orthographic projection of the active pattern c1 on the base substrate 101 and the orthographic projection of the first connection portion d1 on the base substrate 101. That is, a portion of the overlapping region of the orthographic projection of the active pattern c1 on the base substrate 101 and the orthographic projection of the first connection portion d1 on the base substrate 101 is located within the orthographic projection of the signal trace pattern 1022 on the base substrate 101, and another portion is located outside of the orthographic projection of the signal trace pattern 1022 on the base substrate 101.

Provided that the size of the active pattern c1 is a fixed size, the first pattern boundary 1022a of the signal trace pattern 1022 is made to be inwardly retracted, reducing the area of the orthographic projection of the signal trace pattern 1022 on the base substrate 101. Further, the projection overlapping region between the signal trace pattern 1022 and the first connection portion d1 on the base substrate 101 is reduced, reducing the coupling capacitance between the signal trace pattern 1022 and the pixel electrode 105 to which the first connection portion d1 is connected. The first pattern boundary 1022a extends along the first direction X and is closer to the drain region c12 with respect to the source region c11.

Referring to FIG. 44, the active pattern c1 has a first active boundary c1a and a second active boundary c1b that extend along the first direction X and are opposed to each other. The first active boundary c1a is a boundary of the drain region c12 distal to the source region c11, and the second active boundary c1b is a boundary of the source region c11 distal to the drain region c12. The first connection portion d1 has a connection portion boundary dla extending along the first direction X.

Therein, an orthographic projection of the first pattern boundary 1022a on the base substrate 101 is located between an orthographic projection of the first active boundary c1a on the base substrate 101 and an orthographic projection of the connection portion boundary d1a on the base substrate 101, which allows a portion of the active pattern c1 to be located outside of the signal trace pattern 1022, thereby reducing the area of the signal trace pattern 1022.

In some embodiments, a distance between the first pattern boundary 1022a and the connection portion boundary d1a in the second direction Y is less than 3 micrometers (μm). For example, a distance w1 between the first pattern boundary 1022a and the connection portion boundary d1a in the second direction Y is 2.5 μm. In this way, the overlapping region of the orthographic projection of the signal trace pattern 1022 on the base substrate 101 and the orthographic projection of the first connection portion d1 on the base substrate 101 is reduced, thereby reducing the coupling capacitance between the first signal trace 102 and the pixel electrode 105.

Referring to FIG. 44, the signal trace pattern 1022 has a second pattern boundary 1022b extending along the second direction Y and distal to a side of the signal trace body 1021. The active pattern c1 has a third active boundary c1c and a fourth active boundary c1d extending along the second direction Y and opposing each other. The third active boundary c1c is closer to the second pattern boundary 1022b relative to the fourth active boundary c1d is.

In some embodiments, a distance w2 between the second pattern boundary 1022b and the third active boundary c1c in the first direction X is less than or equal to 3 μm. That is, the smaller distance between the second pattern boundary 1022b and the third active boundary c1c in the first direction X allows the second pattern boundary 1022b of the signal trace pattern 1022 to be inwardly retracted, thereby reducing the area of the orthographic projection of the signal trace pattern 1022 on the base substrate 101. Further, the projection overlapping region of the second signal trace 103 and the signal trace pattern 1022 may be reduced, reducing the coupling capacitance between the second signal trace 103 and the first signal trace 102.

Exemplarily, a distance between the second pattern boundary 1022b and the third active boundary c1c in the first direction X is 2 μm.

In some embodiments of the present disclosure, an overlapping region between the orthographic projection of the second signal trace 103 on the base substrate 101 and the orthographic projection of the signal trace pattern 1022 on the base substrate 101 includes a first overlapping region p1 and a second overlapping region p2.

A length of the first overlapping region p1 in the first direction X is less than or equal to a distance between the second pattern boundary 1022b and the third active boundary c1c in the first direction X. A length of the second overlapping region p2 in the first direction X is the length of the distance between the third active boundary c1c and the fourth active boundary c1d in the first direction X.

Since the second overlapping region p2 is the projection overlapping region of the active pattern c1 and the second signal trace 103 and the size of the active pattern c1 affects the size of the channel region c13 of the switching transistor T, the size of the active pattern c1 is not usually adjusted, and it is thus difficult to adjust the area of the second overlapping region p2. Further, in order to reduce the projection overlapping region between the second signal trace 103 and the signal trace pattern 1022, the area of the first overlapping region p1 may be reduced.

In some embodiments, the distance w2 between the second pattern boundary 1022b and the third active boundary c1c in the first direction X is smaller (less than 3 μm), so that the length of the first overlapping region p1 in the first direction X is less than or equal to the distance w1 between the second pattern boundary 1022b and the third active boundary c1c in the first direction X, which makes the area of the first overlapping region p1 smaller, thereby reducing the coupling capacitance between the second signal trace 103 and the first signal trace 102.

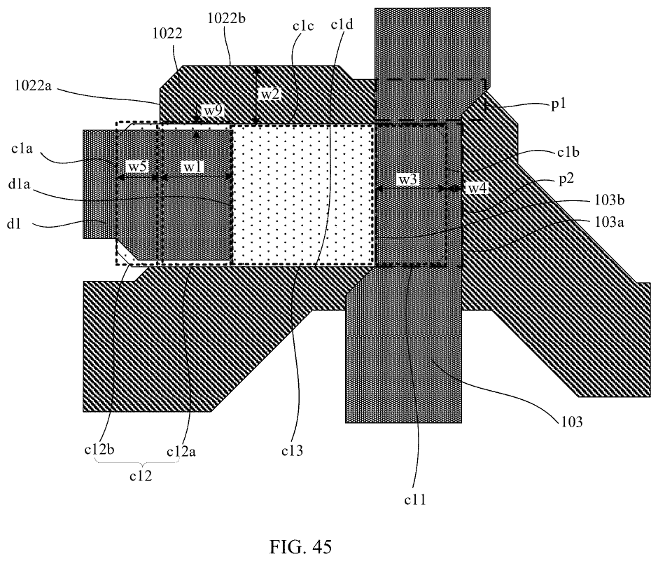

Exemplarily, referring to FIG. 44, a length of the first overlapping region p1 in the first direction X is equal to the distance w1 between the second pattern boundary 1022b and the third active boundary c1c in the first direction X. Alternatively, referring to FIG. 45, a length of the first overlapping region p1 in the first direction X is less than the distance w1 between the second pattern boundary 1022b and the third active boundary c1c in the first direction X.

In some embodiments of the present disclosure, referring to FIG. 44, the second signal trace 103 has a first trace boundary 103a and a second trace boundary 103b extending along the first direction X. The first trace boundary 103a is further distal to the drain region c2 with respect to the second trace boundary 103b, and at least a part of the orthographic projection of the first trace boundary 103a on the base substrate 101 and at least a part of the second trace boundary 103b on the base substrate 101 lies within the orthographic projection of the signal trace pattern 1022 on the base substrate 101.

Thus, the projection overlapping region between the second signal trace 103 and the signal trace pattern 1022 may depend on the distance between the first trace boundary 103a and the second trace boundary 103b of the second signal trace 103 in the second direction Y (i.e., the trace width w3+w4 of the projection overlapping region of the second signal trace 103 and the signal trace pattern 1022). The width of the projection overlapping region of the second signal trace 102 and the signal trace pattern 1022 is the width of the second signal trace 102 in the second direction Y. That is, the width of the second signal trace 102 in the second direction Y may be equal to the sum of a distance w3 between the first trace boundary 103a and the second active boundary c1b in the second direction Y and a distance w4 between the second active boundary c1b and the first trace boundary 102a in the second direction Y.

In some embodiments, the distance (w3+w4) between the first trace boundary 103a and the second trace boundary 103b in the second direction Y is less than or equal to 3 μm. That is, the distance between the first trace boundary 103a and the second trace boundary 103b is smaller, which in turn reduces the projection overlapping region between the second signal trace 103 and the signal trace pattern 1022, thereby reducing the coupling capacitance between the second signal trace 103 and the first signal trace 102.

Referring to FIGS. 44 and 45, the orthographic projection of the second active boundary c1b on the base substrate 101 is located between the orthographic projection of the first trace boundary 103a on the base substrate 101 and the orthographic projection of the second trace boundary 103b on the base substrate 101. That is, the orthographic projection of the second signal trace 103 on the base substrate 101 covers the orthographic projection of the second active boundary c1b of the active pattern c1 on the base substrate 101.

In some embodiments, taking the structure shown in FIG. 44 as an example, the distance w1 between the first pattern boundary 1022a and the connection portion boundary d1a in the second direction Y is 2.5 μm. The distance w2 between the third active boundary c1c and the second pattern boundary 1022b in the first direction X is 3 μm. The distance w3 between the second trace boundary 103b and the second active boundary c1b in the second direction Y is 2.5 μm. The distance w4 between the second active boundary c1b and the first trace boundary 103a in the second direction Y is 0.5 μm. The distance w5 between the first active boundary c1a and the first pattern boundary 1022a in the second direction Y is 1.5 μm. The width w6 of the channel region c13 in the second direction Y is 5 μm, and the width w7 of the channel region c13 in the first direction X is 5 μm. The distance w8 between the fourth active boundary c1d and the boundary, distal to the channel region c13, of the signal trace body 1021 is 3 μm. The distance w9 between the boundary, distal to the signal line body 1021, of the first connection portion d1 and the third active boundary c1c is 0.25 μm. The distance between the first trace boundary 102a and the third pattern boundary 1022c of the signal trace pattern 1022 in the second direction Y is 2.5 μm.

Taking the structure shown in FIG. 45 as an example, the distance w1 between the first pattern boundary 1022a and the connection portion boundary d1a in the second direction Y is 2.5 μm. The distance w2 between the third active boundary c1c and the second pattern boundary 1022b in the first direction X is 2 μm. The length of the first overlapping region p1 in the first direction X is less than the distance w2, for example, the distance w11 is 1.5 μm. The distance w3 between the second trace boundary 103b and the second active boundary c1b in the second direction Y is 2.5 μm. The distance w4 between the second active boundary c1b and the first trace boundary 103a in the second direction Y is 0.5 μm. The distance w5 between the first active boundary c1a and the first pattern boundary 1022a in the second direction Y is 1.5 μm. The width w6 of the channel region c13 in the second direction Y is 5 μm, and the width w7 of the channel region c13 in the first direction X is 5 μm. The distance w8 between the fourth active boundary c1d and the boundary, distal to the channel region c13, of the signal trace body 1021 is 1.5 μm. The distance w9 between the boundary, distal to the signal trace body 1021, of the first connection portion d1 and the third active boundary c1c is 0.25 μm. The distance between the first trace boundary 102a and the third pattern boundary 1022c of the signal trace pattern 1022 in the second direction Y is 2.5 μm.

In some embodiments of the present disclosure, the display panel further includes a liquid crystal layer. The liquid crystal molecules in the liquid crystal layer are deflected under the joint drive of the pixel electrode 105 and the common electrode 106, thereby realizing light transmission of the display panel.

Referring to FIG. 8, a liquid crystal capacitance Clc and a storage capacitance Cst are formed between the pixel electrode 105 and the common electrode 106, which are the required capacitances in the display panel 1. And the coupling capacitance due to the overlapping of the conductive film layers includes: the coupling capacitance Cgd between the gate layer a and the source-drain layer d, the coupling capacitance Cgp between the gate layer a and the pixel electrode 105, the coupling capacitance Cgc between the gate layer a and the common electrode 106, and the coupling capacitance Cdc between the source-drain layer d and the common electrode 106. Thereby, the coupling capacitance of the entire display panel 1 can be reduced by reducing reducing the above four coupling capacitances.

It should be noted that, referring to Table 1, the loading of the display panel 1 mainly consists of two parts, such as including the loading in the gate driver on array (GOA) circuit and the loading of the source driver circuit.

TABLE 1

| Loading of display panel | Capacitor Composition |
|---|---|
| Loading in GOA circuit | Cgc + Cgd + Cgp |
| Loading in source circuit | Cdc + Cgd |

The loading of the GOA circuit is usually related to the coupling capacitance of the gate layer a and the other conductive film layers, such as the loading in the GOA circuit includes: the coupling capacitance Cgd between the gate layer a and the source-drain layer d, the coupling capacitance Cgp between the gate layer a and the pixel electrode 105, and the coupling capacitance Cgc between the gate layer a and the common electrode 106. The loading in the Source circuit is typically related to the coupling capacitance between the source-drain layer d and other conductive film layers, such as the loading in the source circuit includes: the coupling capacitance Cgd between the gate layer a and the source-drain layer d, and the coupling capacitance Cdc between the source-drain layer d and the common electrode 106.

Based on the above analysis, it can be seen that in order to reduce the loading of the display panel, it is usually possible to reduce the coupling capacitance Cgd, coupling capacitance Cgp, coupling capacitance Cgc, and coupling capacitance Cdc.

For the first optional implementation described above, the common electrode 106 has multiple first openings 106a, and the first openings 106a cover the respective connection positions, and the film layer corresponding to the connection positions includes the source-drain layer. In this way, by providing the multiple first openings 106a at the common electrode 106, the coupling capacitance Cdc between the common electrode 106 and the source-drain layer d is reduced.

By detecting the coupling capacitance Cdc, the coupling capacitance Cdc in the solution of the embodiments of the present disclosure is reduced by about 22% relative to the coupling capacitance Cdc in the solution of the prior art. The loading in the source-drain layer d is reduced by about 6%. This corresponds to a reduction in the Loading of the overall source circuit by about 6%.

Moreover, since the common electrode 106 is provided with the first openings 106a, it is necessary to ensure that the display panel is free of light leakage. Referring to FIG. 4, the light leakage area of the display panel 1 is located near the edge of the gate of the switching transistor T. Since the area is shielded with the black matrix layer 107, the display panel 1 is practically free of light leakage.

For the second optional implementation described above, multiple second openings 106b are provided in the common electrode 106 since the orthographic projection of the black matrix layer 107 on the base substrate 101 covers the orthographic projection of the second signal trace 103 on the base substrate 101.

The midline of the black matrix layer 107 covering the second signal trace 103 may overlap the midline of the second signal trace 103. Exemplarily, it is assumed that the width of the second signal trace 103 in the second direction Y is 3 μm, and the width of the black matrix layer 107 covering the second signal trace 103 in the second direction Y is 6 μm, the widths of the black matrix layer 107 beyond the two sides of the second signal trace 103 are 1.5 μm each.

For the display panel, the light leakage refers to a phenomenon that a black screen is not too black or visually not too black due to the fact that the black matrix layer 107 does not effectively shield the light leakage area when the display panel displays the black screen. For a normally black LCD display panel, in the case that the display panel displays the black screen, the source-drain electrode layer d supplies the same magnitude of voltage to the signal transmitted to the pixel electrode 107 and the signal transmitted to the common electrode 106. In this case, there is no electric field between the pixel electrode 107 and the common electrode 106, which makes the liquid crystal molecules in the liquid crystal layer not deflect, thereby avoiding light leakage. Moreover, there is no light leakage in this case without the black matrix layer 107 being shielded.

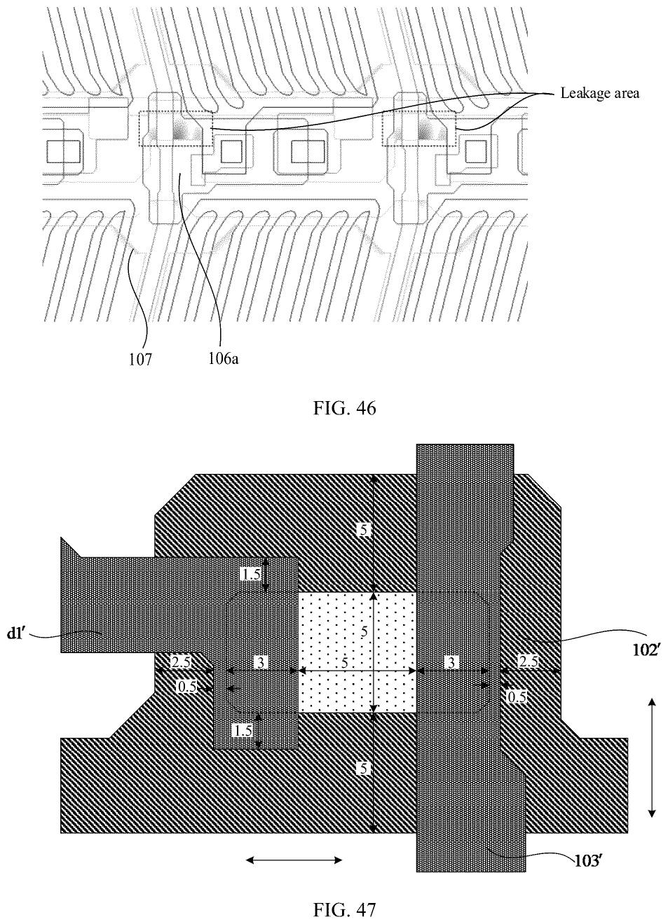

For a high-resolution tablet PC (TPC) product, the second insulating layer e between the source-drain electrode layer d and the common electrode 106 is an organic film layer of a thicker thickness. The thickness of the organic film layer is about 2 μm. Since the electric field formed when the thickness of the third insulating layer g between the common electrode 106 and the pixel electrode 107 is 2500 A (angstroms) or less may drive the liquid crystal molecules to be deflected, the thickness of the third insulating layer g between the common electrode 106 and the pixel electrode 107 is usually 2500 A. However, the thicknesses of the source-drain electrode layer and the upper electrode (common electrode) are greater than 24,000 A, so the electric field formed is extremely small, which in turn causes very little deflection of the liquid crystal molecules. Moreover, the amount of light leakage is very small because the second signal trace 103 has the black matrix layer 107 above it for shading. Also based on the simulation results of FIG. 46, it can be seen that there is no light leakage area in the vicinity of the second signal trace 103. As can be seen, not only can the coupling capacitance Cdc be reduced, but also light leakage cannot be caused according to the second optional implementation.

For the third optional implementation described above, the common electrode 106 has multiple first openings 106a and multiple third openings 106c, and the first openings 106a cover the respective first connection traces 102. In this way, the coupling capacitance Cgc between the common electrode 106 and the gate layer a can be reduced by providing the multiple first openings 106a on the common electrode 106.

For high pixel density (pixels per inch, PPI) products, the first open area 106a on the common electrode 106 does not affect the light leakage since the black matrix layer 107 on the first signal trace 102 is generally more shaded. By testing, it is concluded that the coupling capacitance Cgc is reduced by about 60% and the loading in the gate layer a is reduced by about 8%. This corresponds to a reduction of about 8% in the loading of the entire GOA.

It should be noted that the solution is particularly more suitable for high PPI products where the black matrix layer 107 on the first signal trace 102 covers a wider width, such as the width of the black matrix layer 107 covering the first signal trace 102 in the first direction X is more than 25 μm.

FIG. 47 is a schematic partial diagram of a gate layer, an active layer, and a source-drain layer in the related art. The coupling capacitance Cgd between the gate layer and the source-drain layer is positively correlated to the overlapping region between the gate layer and the source-drain layer. Referring to FIG. 47, the projection overlapping region between the gate layer and the source-drain layer is mainly located in the area of the switching transistor T. The active pattern c1′ is inwardly retracted with respect to the gate layer (i.e., the orthographic projection of the active pattern c1′ on the base substrate is located within the orthographic projection of the gate layer on the base substrate), and the distance between the active pattern c1′ and the first signal trace 102′ in the gate layer is greater than 5 μm in the first direction X. The length of the projection overlapping region of the active pattern c1′ and the first connection portion d1′ in the second direction Y is 3 μm. The width of the second signal trace 103′ is 3 μm. The unit of each dimension shown is μm in FIG. 47.

For the fourth optional implementation described above in FIG. 44, the active pattern c1 in the switching transistor T is outwardly expanded with respect to the signal trace pattern 1022, and the distance w1 between the active pattern c1 and the first connection portion d1 is reduced from 3 μm to 2.5 μm. The distance w2 between the third active boundary c1c of the active pattern c1 and the second pattern boundary of the signal trace pattern 1022 is reduced from 5 μm to 3 um.

With the above design, the projection overlapping region of the signal trace pattern 1022 in the gate layer and the first connection portion d1 in the source-drain layer d is reduced. Moreover, since the first connection portion d1 is connected to the pixel electrode 107, the overlapping region of the signal trace pattern 1022 and the first connection portion d1 is reduced, which causes the coupling capacitance Cgp between the gate layer and the pixel electrode 107 to decrease. The coupling capacitance Cgp is reduced by about 30% as tested.

At the same time, the coupling capacitance Cgd between the gate layer and the second signal trace 103 (source-drain layer) decreases because the projection overlapping region between the gate layer and the second signal trace 103 is also reduced. The coupling capacitance Cgp is reduced by about 25% as tested.

With this optimization scheme, the loading in the gate layer is reduced by about 15%, which corresponds to about 15% reduction in the loading and power consumption of the GOA circuit. The loading in the source-drain layer is reduced by about 10%, which corresponds to about 10% reduction in the loading and power consumption of the source circuit.

When the display panel 1 is in a lit state, the light illumination causes an increase in the number of carriers in the active pattern c1, which causes a large effect on the on-state current Ion and the off-state current Ioff of the switching transistor T, and in particular has a large effect on the off-state current Ioff. An increase in the off-state current Ioff means an increase in the leakage current of the switching transistor T. The increase in the leakage current causes the potential of the pixel electrode 107 to be unretained, which causes a series of display problems such as crosstalk and residual images. Therefore, in the LCD display panel of the related art, if the switching transistor in the display panel is a low-temperature polycrystalline oxide (LTPO) thin-film transistor, the distance of the signal trace pattern 1022 and the active pattern c1 in the first direction X is generally large, such as the distance shown in FIG. 47, which is 5 μm.

However, for the embodiments shown in FIG. 44, a part of the active pattern c1 in the embodiments is exposed outside the signal trace pattern 1022, but the solution does not have any display problem related to the part.

For the fourth optional implementation described above in FIG. 45, in order to reduce the power consumption and capacitance of the second signal trace 103, a solution for further reducing the coupling capacitance Cgd is proposed, that is, to further compress the length w10 of the first overlapping region p1 in the first direction X. For example, the active pattern c1 in the switching transistor T is designed to be outwardly flared with respect to the signal trace pattern 1022, and the overlapping distance w1 between the active pattern c1 and the first connection portion d1 is also reduced from the original 3 μm to 2.5 μm. The distance w2 between the third active boundary c1c of the active pattern c1 and the second pattern boundary of the signal trace pattern 1022 is reduced from 5 μm to 2 um, and the length w10 of the first overlapping region p1 in the first direction X is 1.5 μm.

In order to show that the schemes shown in FIGS. 44 and 45 according to the embodiments of the present disclosure do not affect the on-state current Ion, the off-state current Ioff, the threshold voltage Vth, and the electron mobility (Mob) of the switching transistor T too much, the test element group (TEG) of the schemes shown in FIGS. 44 and 45 at different detection positions in the absence of light and in the presence of light is tested.

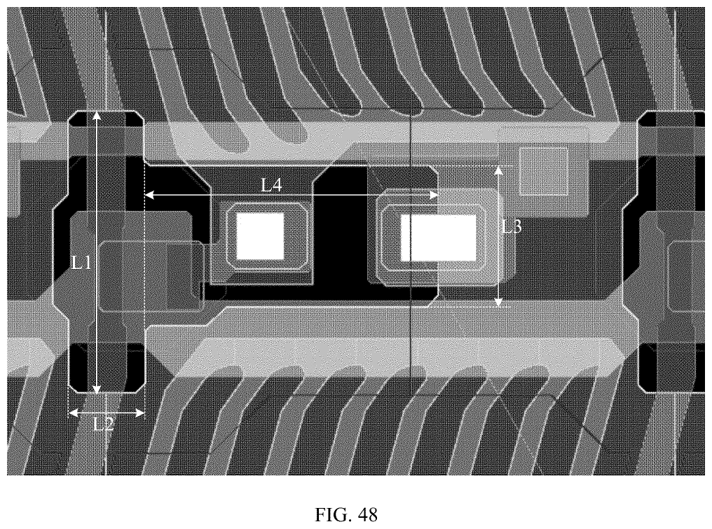

Taking the width-to-length ratio W/L=5/5=1 of the channel region c13 as an example, position 1, position 2, and position 3 of the display panel are tested. Referring to Table 2, it can be seen that in the schemes shown in FIG. 44 and FIG. 45, there is little difference in the on-state current Ion, the off-state current Ioff, the threshold voltage Vth, and the mobility Mob of the switching transistor T with respect to the conventional scheme shown in FIG. 48. Therefore, it is judged that the above schemes have less effect on the characteristics of the switching transistor T and can be practically applied.

TABLE 2

| display panel | | | Ion | Ioff | Vth | Mob |
|---|---|---|---|---|---|---|
| absence | Position 1 | FIG. 47 | 7.82 | −0.15 | 2.63 | 4.76 |
| of light | | FIG. 44 | 7.82 | −0.49 | 2.63 | 4.74 |
| | | FIG. 45 | 7.76 | −0.47 | 2.64 | 4.70 |
| | Position 2 | FIG. 47 | 5.21 | −0.43 | 3.18 | 3.43 |
| | | FIG. 44 | 5.12 | −0.49 | 3.07 | 3.28 |
| | | FIG. 45 | 5.15 | −0.56 | 3.04 | 3.30 |
| | Position 3 | FIG. 47 | 7.29 | −0.41 | 2.89 | 4.66 |
| | | FIG. 44 | 7.16 | −0.38 | 2.85 | 4.54 |
| | | FIG. 45 | 7.05 | −0.59 | 2.89 | 4.50 |
| presence | Position 1 | FIG. 47 | 7.78 | −0.14 | 2.68 | 4.78 |
| of light | | FIG. 44 | 7.78 | −0.40 | 2.69 | 4.76 |
| | | FIG. 45 | 7.70 | −0.52 | 2.73 | 4.73 |
| | Position 2 | FIG. 47 | 5.17 | −0.52 | 3.26 | 3.44 |
| | | FIG. 44 | 5.07 | −0.46 | 3.16 | 3.29 |
| | | FIG. 45 | 5.11 | −0.53 | 3.14 | 3.30 |
| | Position 3 | FIG. 47 | 7.12 | −0.67 | 2.99 | 4.66 |
| | | FIG. 44 | 7.09 | −0.47 | 2.98 | 4.56 |
| | | FIG. 45 | 6.99 | −0.42 | 2.98 | 4.52 |

FIG. 48 is a partially enlarged schematic view of the display panel shown in FIG. 1. Referring to FIG. 48, the length L1 of the first region 106a1 of the first opening 106a in the common electrode 106 in the first direction X ranges from 28 μm to 33 μm, for example, 31 μm. The length L2 of the first region 106a1 in the second direction Y ranges from 12 μm to 18 μm, for example, 15 μm. The length L3 of the second region 106a2 in the first direction X ranges from 27 μm to 33 μm, for example, 30 μm. The length L4 of the second region 106a2 in the second direction Y ranges from 6 μm to 10 μm, for example, 8 μm.

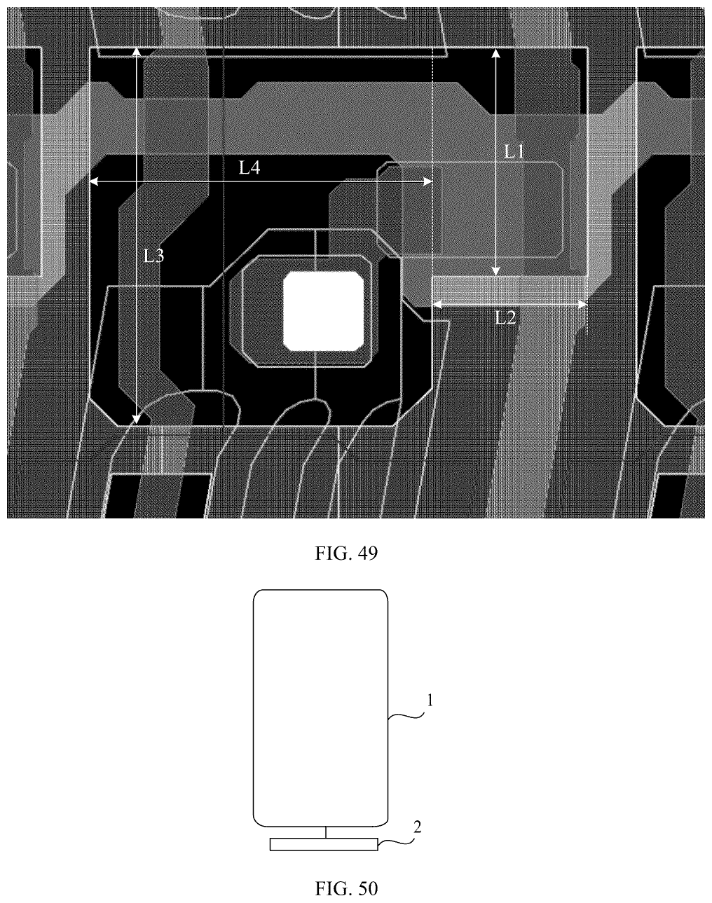

FIG. 49 is a partially enlarged schematic view of the display panel shown in FIG. 5. Referring to FIG. 49, the length L1 of the first region 106a1 of the first opening 106a of the common electrode 106 in the first direction X ranges from 10 μm to 15 μm, for example, 13.4 μm. The length L3 of the second region 106a2 in the first direction X ranges from 20 μm to 25 μm, for example, 23.8 μm. The sum (L2+L4) of the length L2 of the first region 106a1 in the second direction Y and the length L4 of the second region 106a2 in the second direction Y ranges from 28 to 35 μm, for example, 31 μm.

In summary, according to the display panel provided by the embodiments of the present disclosure, the pixel circuit is connected to the first signal trace via the first connection position, is connected to the second signal trace via the second connection position, is connected to the pixel electrode via the third connection position. Moreover, the orthographic projection of the first opening in the common electrode on the base substrate covers the orthographic projections of the connection positions on the base substrate, such that the coupling capacitance between the common electrode and the conductive film layer at the connection positions is avoided, thereby avoiding the abnormal increase of the coupling capacitance at the connection positions. In this way, the display panel is prevent from generating heat, which ensures the yield of the display panel.

FIG. 50 is a schematic structural diagram of a display device according to some embodiments of the present disclosure. Referring to FIG. 50, the display device includes a power assembly 2 and a display panel 1 as provided in the above embodiments. The power assembly 2 is configured to supply power to the display panel 1.

In some embodiments, the display device is an LCD display device. The display device is any product or component with a display function, such as cell phones, tablet computers, televisions, monitors, laptops, digital photo frames, navigators, or e-books.

Since the display device may have basically the same technical effect as the display panel described in the previous embodiments, for the sake of brevity, the technical effects of the display device are not repeated herein.

The terms used in the embodiments of the present disclosure are used only for the purpose of explaining the embodiments of the present disclosure and are not intended to limit the present disclosure. Unless otherwise defined, technical terms or scientific terms used in the embodiments of the present disclosure should have the ordinary meaning understood by a person of ordinary skill in the field to which the present disclosure belongs.

The terms used in the embodiments of the present disclosure are merely intended for the purpose of explaining the embodiments of the present disclosure and are not intended to limit the present disclosure. Unless otherwise defined, technical or scientific terms used in the embodiments of the present disclosure shall have the same meanings as commonly understood by a person of ordinary skill in the art to which the present disclosure belongs. The terms “first,” “second,” “third,” and the like used in the specification and the claims of the present disclosure do not indicate any order, number, or importance, but are used only to distinguish between different components. Likewise, similar words “a” or “an” do not indicate a quantity limitation, but indicate that there is at least one. The terms “include” or “comprise” and the like are intended to indicate that the elements or objects before “include” or “comprise” encompass the elements or objects listed after “include” or “comprise” and their equivalents, and do not exclude other elements or objects. The terms “connect” or “connected” and the like are not limited to physical or mechanical connections, but may include electrical connections, whether direct or indirect. The terms “upper,” “lower,” “left,” “right,” etc. are only used to represent relative position relationships, and when the absolute position of the object to be described changes, the relative position relationship may also be changed accordingly.

The foregoing descriptions are merely optional embodiments of the present disclosure and are not intended to limit the present disclosure. Any modification, equivalent replacement, and improvement within the spirit and principle of the present disclosure shall be included within the protection scope of the present disclosure.

1. A display panel, comprising:
a base substrate;
a plurality of first signal traces disposed on the base substrate, wherein the first signal traces are arranged along a first direction and extend along a second direction, the second direction intersecting with the first direction;
a plurality of second signal traces disposed on the base substrate, wherein the second signal traces are arranged along the second direction and extend along the first direction;
a plurality of pixel circuits arranged in an array, wherein each of the pixel circuits is connected to one of the first signal traces by a first connection position, and is connected to one of the second signal traces by a second connection position;
a plurality of pixel electrodes corresponding to the plurality of pixel circuits, wherein each of the pixel electrodes is connected to a pixel circuit corresponding to the pixel electrode by a third connection position, and the pixel circuit transmits, under a control of the first signal trace, a driving signal from the second signal trace to the pixel electrode;
a common electrode provided with a plurality of first openings corresponding to the plurality of pixel circuits, wherein an orthographic projection of each first opening on the base substrate covers orthographic projections of the first connection position, the second connection position, and the third connection position of the pixel circuit corresponding to the first opening on the base substrate; and
a black matrix layer, wherein an orthographic projection of the black matrix layer on the base substrate covers orthographic projections of the first openings on the base substrate.

2. The display panel according to claim 1, wherein the common electrode is further provided with a plurality of second openings, wherein orthographic projections of the second openings on the base substrate fall within the orthographic projection of the black matrix layer on the base substrate; and
for each of the second openings, an orthographic projection of the second opening on the base substrate covers a part of an orthographic projection of one of the second signal traces on the base substrate, the second opening is disposed between two of the first openings that are adjacent in the first direction, and gaps are defined between the second opening and two of the first openings that are adjacent in the first direction.

3. The display panel according to claim 1, wherein the first opening comprises a first region and a second region in communication with the first region; wherein
an orthographic projection of the first region on the base substrate partially overlaps a projection overlapping region of the first signal trace and the second signal trace, an orthographic projection of the second region on the base substrate at least covers an orthographic projection of the third connection position on the base substrate;
wherein a length of the second region in the first direction is different from a length of the first region in the first direction.

4. The display panel according to claim 1, further comprising a plurality of third signal traces arranged along the first direction and extending along the second direction;
wherein each of the third signal traces is connected to the common electrode.

5. The display panel according to claim 4, further comprising a gate layer, a first insulating layer, an active layer, a source-drain layer, a second insulating layer, a common electrode layer, a third insulating layer, and a pixel electrode layer that are stacked sequentially along a direction away from the base substrate; wherein
the gate layer comprises the plurality of first signal traces and the plurality of third signal traces, the active layer comprises a plurality of active patterns, and the source-drain electrode layer comprises the plurality of second signal traces arranged along the second direction with gaps, a first connection portion, and a second connection portion, the common electrode layer comprises the common electrode, and the pixel electrode layer comprises the plurality of pixel electrodes and a third connection portion; and
a target portion of the second signal trace is connected to the active pattern, one end of the first connection portion is connected to the active pattern, another end of the first connection portion is connected to the pixel electrode, the second connection portion is connected to the common electrodes by the third connection portion, and the second connection portion is connected to the third signal trace.

6. The display panel according to claim 5, wherein an orthographic projection of the third connection portion on the base substrate comprises a first projection region and a second projection region; wherein
the first projection region overlaps the orthographic projection of the first opening on the base substrate, and the second projection region overlaps an orthographic projection of the common electrode on the base substrate; and
a part of the third connection portion corresponding to the first projection region is connected to the second connection portion, and a part of the third connection portion corresponding to the second projection region is connected to the common electrode.

7. The display panel according to claim 4, wherein the orthographic projection of the first opening on the base substrate covers a target overlapping region;
wherein the target overlapping region is an overlapping region of an orthographic projection of the third signal trace on the base substrate and an orthographic projection of the second signal trace on the base substrate.

8. The display panel according to claim 1, further comprising a plurality of fourth signal traces arranged along the second direction and extending along the first direction, wherein each of the fourth signal traces is connected to the common electrode; and
the common electrode is further provided with a plurality of third openings; for each of the third openings, an orthographic projection of the third opening partially overlaps an orthographic projection of one of the fourth signal traces on the base substrate, and the third opening is disposed between two of the first openings that are adjacent in the first direction and gaps are defined between the second opening and two of the first openings that are adjacent in the first direction.

9. The display panel according to claim 8, wherein the orthographic projection of the first opening on the base substrate partially overlaps an orthographic projection of the first signal trace on the base substrate; and
the orthographic projection of the third opening on the base substrate falls outside the orthographic projection of the black matrix layer on the base substrate.

10. The display panel according to claim 8, further comprising a gate layer, a first insulating layer, an active layer, a source-drain layer, a second insulating layer, a common electrode layer, a third insulating layer, and a pixel electrode layer that are stacked sequentially along a direction away from the base substrate; wherein
the gate layer comprises the plurality of first signal traces, the active layer comprises a plurality of active patterns, the source-drain layer comprises the plurality of second signal traces, the plurality of fourth signal traces, and a first connection portion, the common electrode layer comprises the common electrode, and the pixel electrode layer comprises the plurality of pixel electrodes; and
a target portion of the second signal trace is connected to the active pattern, one end of the first connection portion is connected to the active pattern, and another end of the first connection portion is connected to the pixel electrode.

11. The display panel according to claim 5, wherein the pixel circuit comprises a switching transistor, the switching transistor comprising a gate, a source, and a drain; wherein
the first signal trace comprises a signal trace body and a signal trace pattern that are in a one-piece structure, the signal trace pattern serving as the gate of the switching transistor;
an orthographic projection of the active pattern on the base substrate comprises a source region, a drain region, and a channel region between the source region and the drain region, a part of the first connection portion that overlaps and is connected to the drain region serves as the drain of the switching transistor, the target portion of the second signal trace serves as the source of the switching transistor, and the channel region is a region where the signal trace pattern overlaps the active pattern and does not overlap either the first connection portion or the second signal trace.

12. The display panel according to claim 11, wherein an orthographic projection of the source region on the base substrate is located within an orthographic projection of the signal trace pattern on the base substrate;
an orthographic projection of the drain region on the base substrate comprises a third projection region located within the orthographic projection of the signal trace pattern on the base substrate, and a fourth projection region located outside the orthographic projection of the signal trace pattern on the base substrate.

13. The display panel according to claim 12, wherein the active pattern has a first active boundary and a second active boundary that extend along the first direction and are opposed to each other, the first active boundary being a boundary, distal to the source region, of the drain region, and the second active boundary being a boundary, distal to the drain region, of the source region;
the signal trace pattern has a first pattern boundary extending along the first direction, and the first connection portion has a connection portion boundary extending along the first direction; wherein
an orthographic projection of the first pattern boundary on the base substrate is located between an orthographic projection of the first active boundary on the base substrate and an orthographic projection of the connection portion boundary on the base substrate; and
a distance between the first pattern boundary and the connection portion boundary in the second direction is less than 3 micrometers.

14. The display panel according to claim 13, wherein the signal trace pattern has a second pattern boundary extending along the second direction and distal to a side of the signal trace body; the active pattern has a third active boundary and a fourth active boundary that extend along the second direction and are opposed to each other, the third active boundary being closer to the second pattern boundary relative to the fourth active boundary being;
wherein a distance between the second pattern boundary and the third active boundary in the first direction is less than or equal to 3 micrometers.

15. The display panel according to claim 14, wherein an overlapping region between an orthographic projection of the second signal trace on the base substrate and the orthographic projection of the signal trace pattern on the base substrate comprises a first overlapping region and a second overlapping region; wherein
a length of the first overlapping region in the first direction is less than or equal to the distance between the second patterned boundary and the third active boundary in the first direction, and a length of the second overlapping region in the first direction is a distance between the third active boundary and the fourth active boundary in the first direction.

16. The display panel according to claim 15, wherein the second signal trace has a first trace boundary and a second trace boundary extending along the first direction, at least a part of an orthographic projection of the first trace boundary on the base substrate and at least a part of an orthographic projection of the second trace boundary on the base substrate are both located within the orthographic projection of the signal trace pattern on the base substrate; and
a distance between the first trace boundary and the second trace boundary in the second direction is less than or equal to 3 micrometers.

17. The display panel according to claim 1, further comprising an array substrate and a color filter substrate that are oppositely arranged to form a cell, and a liquid crystal layer disposed between the array substrate and the color filter substrate; wherein
the array substrate comprises the plurality of first signal traces, the plurality of second signal traces, the plurality of pixel circuits, the plurality of pixel electrodes, and the common electrode; and the color filter substrate comprises the black matrix layer.

18. A display device, comprising a power assembly and a display panel;
wherein the power assembly is configured to supply power to the display panel; and the display panel comprises:
a base substrate;
a plurality of first signal traces disposed on the base substrate, wherein the first signal traces are arranged along a first direction and extend along a second direction, the second direction intersecting with the first direction;
a plurality of second signal traces disposed on the base substrate, wherein the second signal traces are arranged along the second direction and extend along the first direction;
a plurality of pixel circuits arranged in an array, wherein each of the pixel circuits is connected to one of the first signal traces by a first connection position, and is connected to one of the second signal traces by a second connection position;
a plurality of pixel electrodes corresponding to the plurality of pixel circuits, wherein each of the pixel electrodes is connected to a pixel circuit corresponding to the pixel electrode by a third connection position, and the pixel circuit transmits, under a control of the first signal trace, a driving signal from the second signal trace to the pixel electrode;
a common electrode provided with a plurality of first openings corresponding to the plurality of pixel circuits, wherein an orthographic projection of each first opening on the base substrate covers orthographic projections of the first connection position, the second connection position, and the third connection position of the pixel circuit corresponding to the first opening on the base substrate; and
a black matrix layer, wherein an orthographic projection of the black matrix layer on the base substrate covers orthographic projections of the first openings on the base substrate.

19. The display device according to claim 18, wherein the common electrode is further provided with a plurality of second openings, wherein orthographic projections of the second openings on the base substrate fall within the orthographic projection of the black matrix layer on the base substrate; and
for each of the second openings, an orthographic projection of the second opening on the base substrate covers a part of an orthographic projection of one of the second signal traces on the base substrate, the second opening is disposed between two of the first openings that are adjacent in the first direction, and gaps are defined between the second opening and two of the first openings that are adjacent in the first direction.

20. The display device according to claim 18, wherein the first opening comprises a first region and a second region in communication with the first region; wherein
an orthographic projection of the first region on the base substrate partially overlaps a projection overlapping region of the first signal trace and the second signal trace, an orthographic projection of the second region on the base substrate at least covers an orthographic projection of the third connection position on the base substrate;
wherein a length of the second region in the first direction is different from a length of the first region in the first direction.
